(19) United States
(12) Patent Application Publication
(10) Pub. No.: US 2010/0053386 A1
(43) Pub. Date: Mar. 4, 2010

(54) IMAGING DEVICE, METHOD OF DRIVING IMAGING DEVICE AND IMAGING APPARATUS

(75) Inventor: Makoto SIZUKUISI, Kanagawa (JP)

Correspondence Address: Studebaker & Brackett PC, One Fountain Square, 11911 Freedom Drive, Suite 750, Reston, VA, 20190, US

(73) Assignee: FUJIFILM CORPORATION, Tokyo (JP)

(21) Appl. No.: 12/550,015

(22) Filed: Aug. 28, 2009

(30) Foreign Application Priority Data
Aug. 29, 2008 (JP) 2008-222742
Aug. 28, 2009 (JP) 2009-197753

(51) Int. Cl. H04N 5/335

(52) U.S. Cl. 348/273; 348/294; 348/E05.091

(57) ABSTRACT

An imaging device includes: a semiconductor substrate; a photoelectric converting film that is forms on the semiconductor substrate and that generates charges corresponding to an incident light; a plurality of pixel portions that receive the charges from the photoelectric converting film, a floating gate that is electrically connected to the photoelectric converting film; and a transistor that fluctuates a threshold voltage so as to start to increase a drain current when an electric potential of the floating gate changes.

### CROSS-REFERENCE TO RELATED APPLICATIONS

The present application claims priority from Japanese Patent Application No. 2008-222742 filed on Aug. 29, 2008 and Japanese Patent Application No. 2009-197753 filed on Aug. 28, 2009; the entire content of which is incorporated herein by reference.

### BACKGROUND OF INVENTION

1. Field of the Invention

The present invention relates to an imaging device including a photoelectric converting film, a method of driving the imaging device, and an imaging apparatus.

2. Description of the Related Art

Examples of an imaging device include a CMOS type image sensor and an interline CCD type image sensor. The imaging device has a plurality of photodiodes arranged on a semiconductor substrate, and each of the photodiodes constitutes each pixel portion. An opening formed on a metal shielding film is provided on the photodiode of the pixel portion, and a microlens for collecting an incident light onto the photodiode is provided on a light incident side of the opening. With the structure, in the case in which a fineness of the pixel portion is to be enhanced, an optical sensitivity and a saturated charge quantity (a D range) of the imaging device are reduced due to a decrease in a quantity of the light collected through the microlens every pixel portion and a reduction in a light receiving area of the photodiode. In the imaging device, if the opening area is reduced due to the enhancement in the fineness of a pixel, it is hard to transmit a visible light wavelength (for example, 0.62 mμm in a red light R).

Therefore, there has been started to be reconsidered a so-called stack type imaging device having a structure in which a photoelectric converting film containing a photoelectric converting material for generating a charge by receiving an incident light is stacked. The stack type imaging device has such a structure as to receive the light by the photoelectric converting film, to generate a signal charge by a photoelectric converting function, and to read the signal charge every pixel by a CCD circuit or a CMOS circuit. For this reason, the stack type imaging device does not have such a structure as to transmit an incident light through an opening of a shielding film and to receive the light by a photodiode. Therefore, there is an advantage in that a transmission efficiency of the incident light is prevented from being reduced due to an enhancement in a fineness of a pixel.

For a material of the photoelectric converting film, it is possible to apply an amorphous Si film, an amorphous Se film, a Saticon film or a Newvicon film which has been used in an image pickup tube. Moreover, an application of an organic photoelectric converting film has also been considered for the photoelectric converting film.

The following JP-A-2002-280537 and JP-A-8-316450 have described relational imaging devices, for example.

JP-A-2002-280537 relates to a solid state imaging device having a nonvolatile memory structure in which a plurality of pixel portions is formed on a semiconductor substrate, each of the pixel portions includes a light receiving device for receiving an incident light and generating a signal charge, and a connection to the light receiving device is carried out and a signal voltage corresponding to the fetched signal charge can be generated.

JP-A-8-316450 has described a solid state imaging device having a structure in which a photoelectric converting film formed on a silicon substrate and an MOS device are provided, and the photoelectric converting film is directly formed on the silicon substrate.

FIG. 16 is a diagram showing an example of a structure of a relational MOS type imaging device. FIG. 16 illustrates a structure of an imaging device having a so-called passive type MOS transistor. In the imaging device, a large number of pixel portions are disposed in a matrix on a surface of a semiconductor substrate. A photoelectric converting film for generating a charge by receiving a light is provided on the large number of pixel portions. Each of the pixel portions includes a single MOS type transistor. Each of the pixel portions is provided with a charge storage region for storing the charge generated in the photoelectric converting film. A row selecting line is connected to a gate of each transistor and a vertical signal line is connected to a drain thereof. The row selecting lines are connected to a vertical shift register, respectively. The vertical signal line is connected to an output amplifier via a CDS circuit and a horizontal selecting transistor, respectively. Moreover, a reset transistor is connected to each of the vertical signal lines. A timing signal is supplied from a timing generator (not shown) to the vertical shift register and a horizontal shift register. The pixel portion corresponding to a single row is selected by the vertical shift register, and furthermore, the horizontal shift register sequentially selects each column and supplies a charge corresponding to a single row to the output amplifier.

An imaging device having a photoelectric converting film stacked thereon uses a method of taking an ohmic contact with the photoelectric converting film and a surface of a semiconductor substrate through a contact via, thereby reading a charge generated in the photoelectric converting film through the contact via by a reading wiring. In the method, a surface portion of the semiconductor substrate taking the ohmic contact is to be an impurity layer having a high concentration (for example, an N+ type impurity diffusion region). However, the impurity layer having a high concentration serves as a dark current source, which is a great factor of a deterioration in an optical characteristic of a device. In particular, a dark current is increased exponentially with a rise in a temperature. For this reason, it is impossible to avoid a deterioration in picture quality due to a dark current noise. In the imaging device of an optical conductive film stack type, therefore, there is room for improving a signal reading method.

### SUMMARY OF INVENTION

In consideration of the circumstances, it is an object of the invention to provide an imaging device which has a photoelectric converting film stacked on a semiconductor substrate, has a novel reading method, can prevent a reduction in a sensitivity with an enhancement in a fineness of a pixel and can avoid an increase in a dark current, a method of driving the imaging device, and an imaging apparatus.

(1) According to an aspect of the invention, an imaging device includes a semiconductor substrate; a photoelectric converting film that is forms on the semiconductor substrate and that generates a charge corresponding to an incident light; and a plurality of pixel portions that receive the charge from the photoelectric converting film, wherein each of the pixel portions includes: a floating gate that is electrically connected to the photoelectric converting film; and a transistor that fluctuates a threshold voltage corresponding to an electric potential of the floating gate.
(2) According to an aspect of the invention, a method of driving an imaging device including; a semiconductor substrate; a photoelectric converting film that is forms above the semiconductor substrate and that generates a charge corresponding to an incident light; and a plurality of pixel portions that receive the charge from the photoelectric converting film, wherein each of the pixel portions includes: a floating gate that is electrically connected to the photoelectric converting film; and a transistor that fluctuates a threshold voltage corresponding to an electric potential of the floating gate; the method includes; transmitting a quantity of the charge or a change in an electric potential from the photoelectric converting film to the floating gate and detecting a value of the threshold voltage fluctuating corresponding to the electric potential of the floating gate, thereby outputting a signal.
(3) An imaging apparatus includes an imaging device according to (1).

According to the invention, it is possible to provide an imaging device which can prevent a sensitivity from being reduced with an enhancement in a fineness of a pixel by a structure in which a photoelectric converting film is stacked above a semiconductor substrate, and furthermore, has a novel reading method and can avoid an increase in a dark current, a method of driving the imaging device, and an imaging apparatus.

### BRIEF DESCRIPTION OF THE DRAWINGS

FIGS. 1A and 1B are a diagram for explaining a structure according to an embodiment of an imaging device in accordance with the invention,

FIG. 2 is a sectional view typically showing a structure of each pixel portion in the imaging device of FIGS. 1A and 1B,

FIGS. 3A and 3B are a diagram showing an operation principle of a transistor in the pixel portion of the imaging device in FIGS. 1A and 1B,

FIG. 4 is a timing chart showing the case in which still image pickup is carried out by the imaging device in FIG. 1A,

FIG. 5 is a sectional view showing a structure according to another embodiment of the imaging device in accordance with the invention,

FIGS. 6A, 6B and 6C are a circuit diagram showing each pixel portion of the imaging device in FIG. 5,

FIG. 7 is a timing chart showing the case in which still image pickup is carried out by the imaging device of FIG. 5,

FIG. 8 is a sectional view showing a structure according to yet another embodiment of the imaging device in accordance with the invention,

FIGS. 9A, 9B and 9C are circuit diagrams showing each pixel portion of the imaging device in FIG. 8,

FIG. 10 is a sectional view showing a structure of a part of pixel portions according to a further embodiment of the imaging device in accordance with the invention,

FIG. 11 is a view for explaining a principle of a writing operation of a second transistor in the imaging device of FIG. 10,

FIG. 12 is a sectional view showing a structure of another pixel portion of the imaging device in FIG. 10,

FIG. 13 is a sectional view showing a structure according to a further embodiment of the imaging device in accordance with the invention,

FIGS. 14A, 14B and 14C are circuit diagrams showing each pixel portion of the imaging device in FIG. 13,

FIG. 15 is a timing chart showing the case in which still image pickup is carried out by the imaging devices illustrated in FIGS. 10, 12 and 13, and

FIG. 16 is a diagram showing an example of a structure of a relational MOS type imaging device.

### DESCRIPTION OF EXEMPLARY EMBODIMENTS

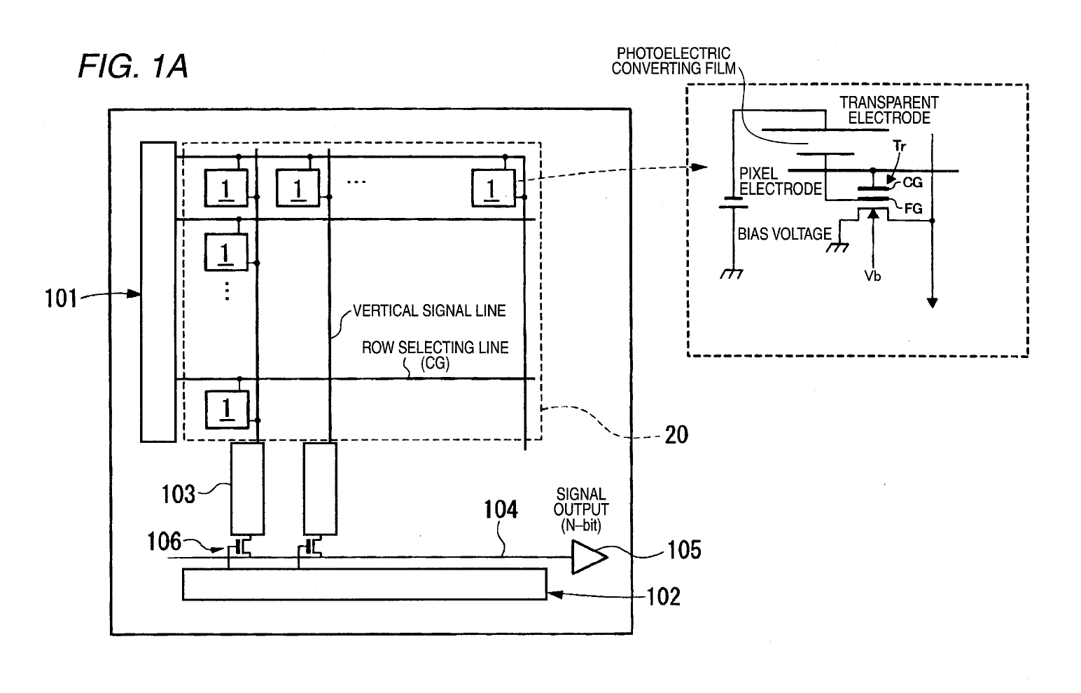

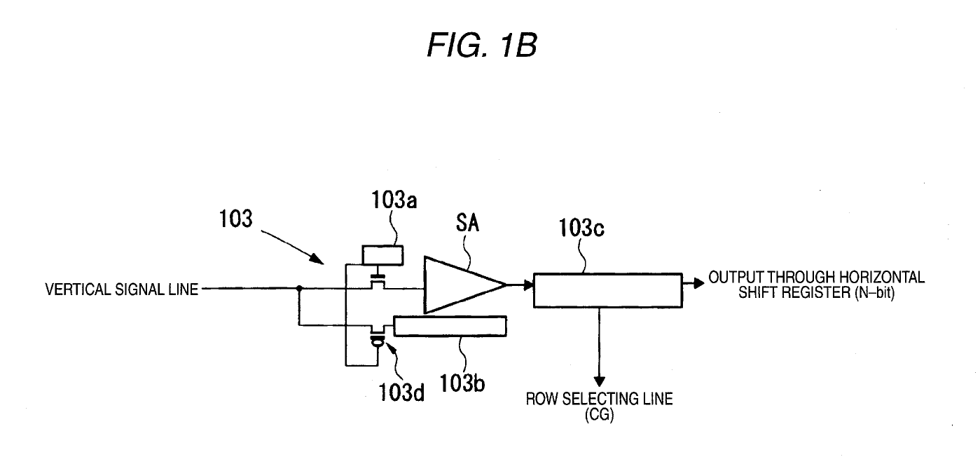

An embodiment according to the invention will be described below in detail with reference to the drawings. FIG. 1A is a typical diagram showing a structure of an embodiment of an imaging device. FIG. 1B is a circuit diagram showing a reading circuit. The imaging device has a large number of pixel portions 1 disposed in a matrix on a surface of a semiconductor substrate. At a light incident side of the large number of pixel portions 1, a photoelectric converting film 20 is provided to cover all of the pixel portions 1.

FIG. 1A shows an equivalent circuit for one of the pixel portions. Each of the pixel portions includes a transistor Tr having a single MOS type structure. A floating gate (hereinafter referred to as an FG) connected electrically to the photoelectric converting film 20 and a control gate (hereinafter referred to as a CG) functioning as a gate of the transistor Tr are formed in each of the pixel portions 1. A source of the transistor Tr is grounded. The transistor Tr has a structure in which a light is incident on the photoelectric converting film 20 to carry out a photoelectric converting action so that an electric potential of the FG connected electrically to the photoelectric converting film 20 is changed and a threshold voltage of the transistor Tr fluctuates corresponding to the electric potential of the FG, and outputs a drain signal as a function of the threshold voltage. Moreover, the transistor Tr has a structure in which a back bias voltage Vb for setting the electric potential of the FG into an unchanged and predetermined value can be applied.

Row selecting lines are connected to a gate side of each transistor Tr and vertical signal lines are connected to a drain side thereof. The row selecting lines are connected to a vertical shift register 101, respectively. The vertical signal lines are connected to a reading circuit 103. The reading circuit 103 is connected to a horizontal selecting transistor 106 and a signal line 104. The signal line 104 is connected to an output amplifier 105. A timing signal is supplied from a timing generator (not shown) to the vertical shift register 101 and a horizontal shift register 102. The vertical shift register 101 selects the pixel portion 1 corresponding to a single row and the horizontal shift register 102 sequentially selects each column, and a signal of each pixel portion 1 thus selected is output from the output amplifier 105.

The reading circuit 103 detects a threshold voltage corresponding to a change in an electric potential of a drain which is precharged to the transistor Tr of each pixel portion 1.

As shown in FIG. 1B, the reading circuit 103 includes a reading control portion 103a, a precharging circuit 103b, a sense amplifier SA, a ramp-up circuit 103c, and a transistor 103d. When reading a signal from the pixel portion 1, the reading control portion 103a turns ON the transistor 103d to precharge an electric potential of the vertical signal line (the drain) of the pixel portion 1 from the precharging circuit 103b and turns ON the transistor 103d to conduct the drain of the pixel portion 1 to the sense amplifier SA.

The sense amplifier SA monitors the electric potential of the vertical signal line of the pixel portion 1 and inverts the sense amplifier's output signal level from “1” to “0” or “0” to “1” when detecting that the electric potential is changed. The ramp-up circuit 103c receiving the inverted signal temporarily holds (latches) a counter value of a counter circuit in the ramp-up circuit 103c at that time.

More specifically, the ramp-up circuit 103c supplies a lamp voltage. The lamp voltage is supplied to each of the CG of the pixel portions 1 from the vertical shift register 101. The ramp-up circuit 103c includes an N-bit counter for generating the lamp voltage and an N-bit counter value at that time corresponds to the threshold voltage upon receipt of the inverted signal from the sense amplifier SA. According to the reading method, the threshold voltage can be read as N-bit digital data and an analog/digital (A/D) conversion can also be implemented at the same time.

When one of the horizontal selecting transistors 106 is selected by the horizontal shift register 102, the counter value held by the ramp-up circuit 103c connected to the same horizontal selecting transistor 106 is output to the signal line 104 and is output as an imaging signal from the output amplifier 105.

The vertical shift register 101 independently applies a gate voltage supplied from the ramp-up circuit 103c to the CG of each pixel portion 1 every line. The vertical shift register 101 also carries out a charge erase control for batch erasing charges stored in the FG of each pixel portion 1.

In the embodiment, as an example, a large number of pixel portions 1, the vertical shift register 101, the horizontal shift register 102, the reading circuit 103, the horizontal selecting transistor 104 and the output amplifier 105 are provided into a single chip on a semiconductor substrate 11, and the single chip product is set to be an imaging device. However, the imaging device can have a structure in which at least a large number of pixel portions 1 are formed on the semiconductor substrate 11.

In the invention, it is possible to provide an imaging apparatus including at least the imaging device. The imaging apparatus can have such a structure as to include a driving circuit for driving the imaging device, a control portion and a buffer in addition to the imaging device.

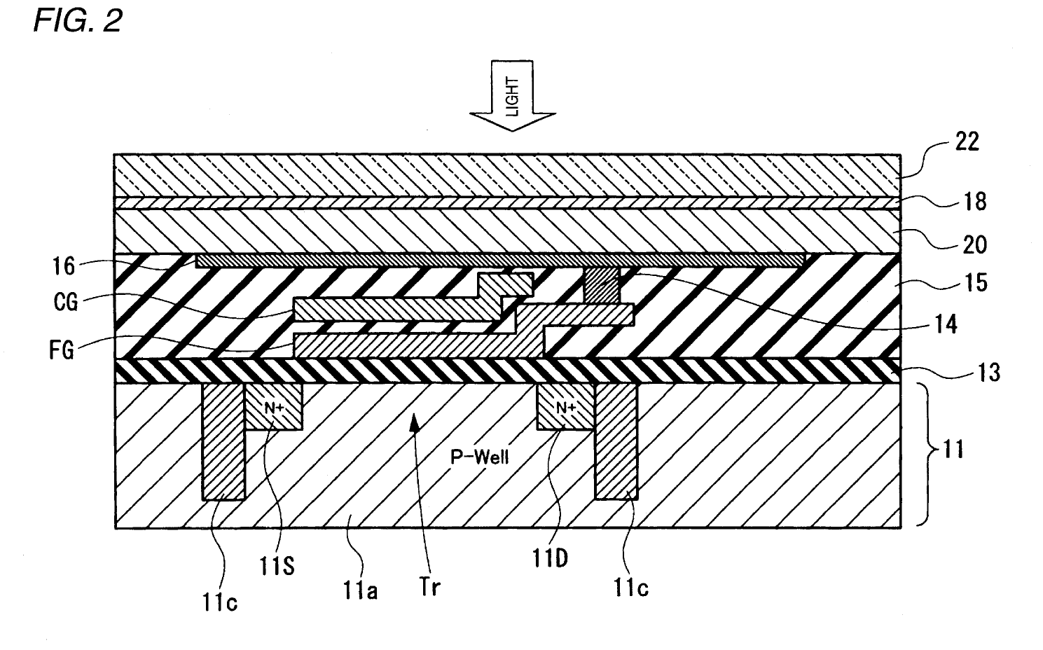

FIG. 2 is a sectional view typically showing a structure of each of the pixel portions in the imaging device illustrated in FIG. 1A. As shown in FIG. 2, in the description of the structure of the imaging device according to the embodiment, a side on which a light is incident will be set to be “upper” or “above” and an opposite side thereto will be set to be “lower” or “below”.

A P well 11a is formed in a surface region of the semiconductor substrate 11 formed by an N-type silicon substrate. A surface of the P well 11a is provided with an N+ type impurity diffusion region (hereinafter referred to as a source) 11S having a high concentration and functioning as the source of the transistor Tr and an N+ type impurity diffusion region (hereinafter referred to as a drain) 11D having a high concentration and functioning as the drain. The source 11S is grounded and the drain 11D is connected to the vertical signal line. Moreover, a device isolation region 11c for isolating adjacent pixels to each other is formed on a surface of the semiconductor substrate 11. The device isolation region 11c can be formed by a thick oxide film SiO₂ formed by the LOCOS method or the CVD method, STI (Shallow Trench Isolation) or an ion implantation of boron (B). Although the P well 11a is formed in the surface region of the semiconductor substrate 11 formed by the N type silicon substrate in the imaging device according to the embodiment, a conductivity type of the semiconductor substrate 11 is not particularly restricted in the invention but a P type silicon substrate may be used to provide the N+ type impurity diffusion regions 11S and 11D on a surface thereof.

Although the following description will be given by taking, as an example, a structure in which an electron is set to be a charge, a hole can also be set to be the charge in the imaging device according to the invention. In the case in which the hole is set to be the charge, a structure in which all of the conductivity types of the semiconductor substrate 11 and the impurity diffusion region may be reversed.

A gate oxide film 13 is formed on the surface of the semiconductor substrate 11. Moreover, the gate oxide film 13 is provided on the semiconductor substrate 11 and the FG to be an electrical floating electrode is provided above the gate oxide film 13. An insulating layer 15 is stacked above the gate oxide film 13. The FG is provided inside the insulating layer 15, the insulating layer 15 is provided on the FG, and the CG is provided on the insulating layer 15. The FG and the CG are formed by patterning impurity doped polysilicon.

Although there is employed a two-layer structure in which the insulating layer 15 is provided on the FG and the CG is provided on the insulating layer 15 to overlap therewith in the embodiment, moreover, the structures of the FG and the CG are not restricted thereto but it is possible to properly change a configuration in which the CG overlaps with an upper side of the FG in at least an upper part of a portion in which a channel of the transistor Tr is formed if any.

A pixel electrode 16 is provided on an upper surface of the insulating layer 15. The photoelectric converting film 20 and a transparent counter electrode 18 opposed to the pixel electrode 16 with the photoelectric converting film 20 interposed therebetween are provided on the pixel electrode 16. For the photoelectric converting film 20, an amorphous silicon film, an organic photoelectric converting film or a CIGS (CuInGaSe) film is used, for example.

The transparent counter electrode 18 and the photoelectric converting film 20 which are single in common are formed to cover all of the pixel portions 1, respectively. A protective film 22 is provided on an upper surface of the transparent counter electrode 18. The transparent counter electrode 18 has such a structure that a negative bias voltage is applied in an exposure.

One of ends of a contact via 14 taking an almost columnar shape and extended in a vertical direction of the imaging device is connected to a lower side surface of the pixel electrode 16, and the other end of the contact via 14 is connected to the FG. The contact via 14 functions as a wiring portion for being connected to the pixel electrode 16, connecting the photoelectric converting film 20 to the FG electrically, and transmitting a quantity of a charge or a change in an electric potential from the photoelectric converting film 20 to the FG.

The contact via 14 and a portion of the FG which is provided in contact with the contact via 14 should be formed on the device isolation region or the FG extended over the thick insulating layer 15 provided on the gate oxide film 13 in the case in which the insulating layer 15 between the semiconductor substrate 11 and the FG is thicker than the other parts. Consequently, it is possible to prevent a fluctuation in the electric potential of the semiconductor substrate 11 or the P well 11a from being caused by a fluctuation in an electric potential of the FG.

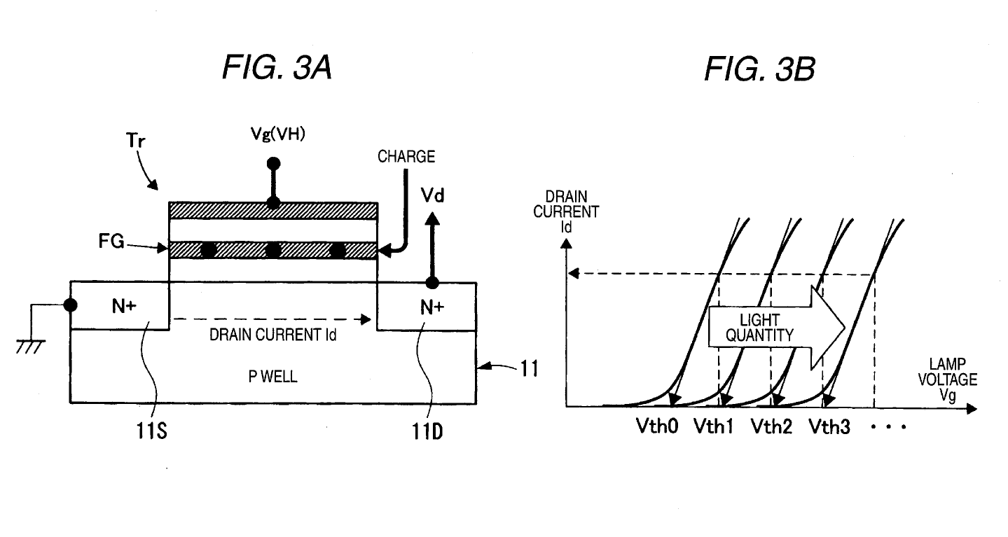

FIGS. 3A and 3B show an operation principle of a transistor in each of the pixel portions, and FIG. 3A is a typical view showing a movement of a charge and a flow of a current in an operation and FIG. 3B is a chart showing a change in a threshold voltage Vth of the transistor Tr with an increase in a drain current Id. As shown in FIG. 3A, the transistor Tr applies the drain voltage Vd, and the transistor can define a gate voltage, that is a threshold voltage Vth, that the drain current Id starts to increase so that a channel region between the source 11S and the drain 11D is conducted when a voltage of a gate Vg is varied. The threshold voltage Vth corresponding to the gate voltage Vg in the conduction of the channel region has such a characteristic for changing depending on a magnitude of the electric potential of the FG.

In the imaging device according to the embodiment, when a light is irradiated on the photoelectric converting film 20 in an imaging operation, a charge is generated by a photoelectric converting function so that the electric potential of the FG is changed depending on the quantity of the charge. At this time, a lamp voltage is supplied to the CG. The lamp voltage in a change of the electric potential (Vd) of the precharged drain is set to be threshold voltages Vth0, Vth1, Vth2, Vth3 and others, respectively. If the electric potential of the FG is high, that is, a quantity of the light received by the photoelectric converting film 20 is increased, the threshold voltages Vth0, Vth1, Vth2 and Vth3 corresponding to the change in the electric potential of the drain are raised. When the charge is to be read, a ramp-up operation for gradually increasing the lamp voltage Vg to be applied to the CG is carried out by the ramp-up circuit 103c. At that time, the lamp voltage Vg of the CG in the change in the electric potential Vd of the drain is detected by the sense amplifier SA and is output as a threshold voltage based on a counter value of the ramp-up circuit 103c. Consequently, it is possible to obtain a signal output corresponding to a quantity of a light which is incident on the photoelectric converting film 20. The ramp-up operation for gradually increasing the lamp voltage Vg is not restricted to the case in which the lamp voltage Vg is continuously increased but also includes the case in which step-up voltage is carried out. Moreover, it is also possible to carry out a ramp-down operation for gradually decreasing the lamp voltage Vg. In this case, the gradual decrease is not restricted to the case in which a continuous decrease is performed but includes the case in which step-down is gradually carried out. In the following, description will be given by taking an example in which the ramp-up operation is carried out.

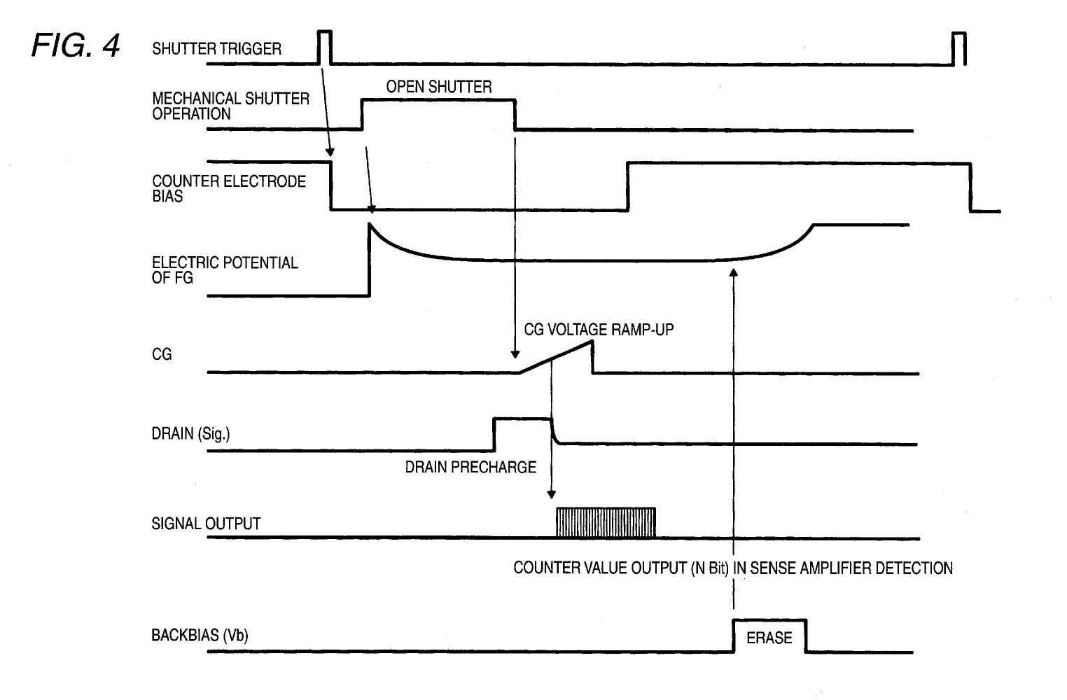

Next, description will be given to an operation for picking up a still image through the imaging device according to the embodiment. FIG. 4 is a timing chart showing the case in which the still image pickup is carried out by the imaging device.

When imaging condition setting (AE or AF) for the still image pickup is previously carried out and the still image pickup operation (for fully pressing a shutter button) is executed, a shutter trigger rises so that the still image pickup is started on the set imaging condition.

When the shutter trigger rises, a bias voltage of the transparent counter electrode 18 is set to have a low level so that the quantity of the charge or the change in the electric potential generated in the photoelectric converting film 20 can be transmitted to the FG. When a timing for starting an exposure period is set after the shutter trigger rises, a mechanical shutter for transmitting or shielding a light which is incident on the imaging device through a mechanical opening/closing driving operation is opened and is maintained to be opened till a timing for ending the exposure period. It is also possible to bean electronic shutter driving method for electronically executing a shutter operation provided in place of the mechanical shutter.

When the mechanical shutter is opened, a light is incident from an object onto the photoelectric converting film 20 and the charge is generated by the light which is incident on the photoelectric converting film 20. By the charge generated in the photoelectric converting film 20, the electric potential of the FG is changed.

Before the mechanical shutter is closed, a drain voltage is applied to the drain 11D of each of the pixel portions 1 and the drain 11D is thus precharged. “Drain (Sig.)” shown in FIG. 4 indicates a change in an electric potential of the drain 11D.

When the voltage of the CG in each of the pixel portions 1 in a first line is ramped up so that the channel region of the transistor Tr is conducted, next, the electric potential of the drain 11D is dropped. The sense amplifier detects, as a counter value, the value of the CG obtained when the electric potential of the drain 11D is dropped, and outputs a threshold voltage corresponding to the counter value as an N-bit imaging signal. “Signal Output” shown in FIG. 4 indicates an imaging signal to be output.

Referring to each of the pixel portions 1 after a second line, similarly, the ramp-up operation (or the ramp-down operation) for the gate voltage of the CG is sequentially carried out and an imaging signal is sequentially output from each line.

When the imaging signals are output from all of the pixel portions 1 so that the still image pickup is ended, the charges stored in the FG of each of the pixel portions 1 to prepare for next still image pickup are batch erased. Examples of a method of batch erasing the charges include a method of applying a negative voltage to the CG and applying a positive voltage to the semiconductor substrate 11, thereby extracting and discharging the charges in the FG to the semiconductor substrate 11 side. “BackBias (Vb)” shown in FIG. 4 indicates a change in a back bias voltage to be applied when batch erasing the charges.

According to the structure of the imaging device in accordance with the embodiment, the charge generated in the photoelectric converting film 20 is transmitted to the FG and the signal corresponding to the change in the electric potential of the FG is output. It is not necessary to form a pn junction photodiode in the semiconductor substrate 11. Therefore, the imaging device is rarely influenced by a reduction in a sensitivity with an enhancement in the fineness of the pixel portion 1 and can carry out an imaging operation having a high sensitivity.

Moreover, there is employed the method of being read the charge generated in the photoelectric converting film 20 onto the FG through the contact via 14, and it is not necessary to provide an impurity region having a high concentration for taking an ohmic contact in the surface portion of the semiconductor substrate 11. Therefore, it is possible to relieve a deterioration in picture quality which is caused by a dark current noise.

In case of a conventional CMOS image sensor, four transistors are required in each of the pixel portions for reading photo-generated charges. According to the structure in accordance with the embodiment, however, it is possible to provide only one transistor in each of the pixel portions. Therefore, it is possible to enhance the fineness of the pixel portion.

According to the structure of the imaging device in accordance with the embodiment, furthermore, the threshold voltage of the transistor Tr is output as a signal based on the change in the electric potential of the FG. Therefore, it is possible to reduce a capacitive image lag which is caused by an imperfect reading of signal charges stored in the storage region of the pixel portion 1.

Next, description will be given to another embodiment of the imaging device. In the embodiment which will be described below, members having equivalent structures and functions to the members described above have the same designations or corresponding designations in the drawings, and the description will be thus simplified or omitted.

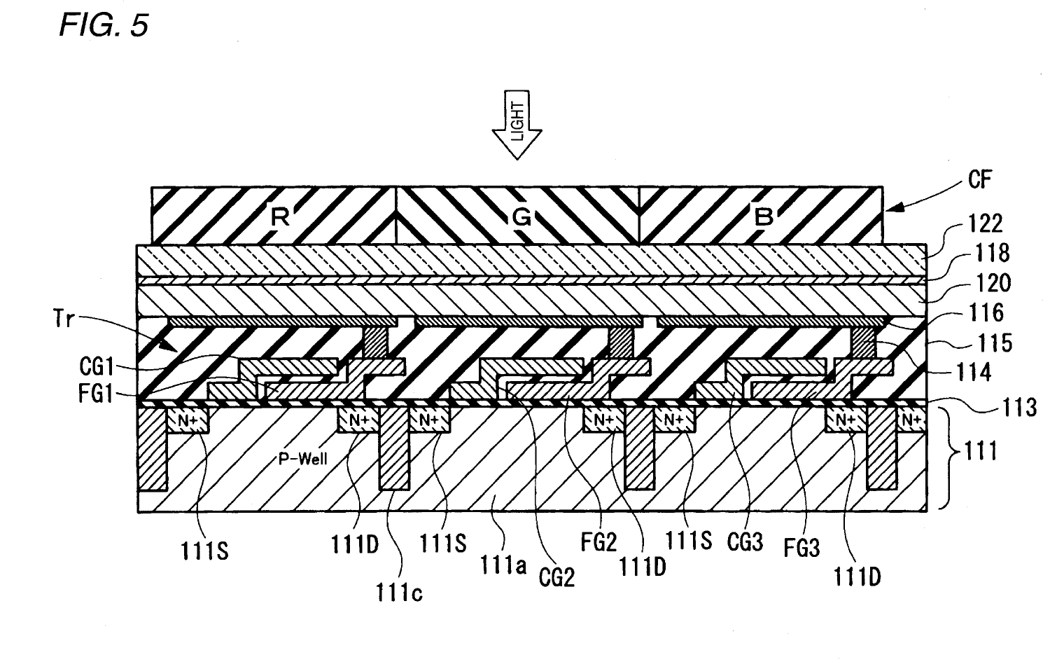

FIG. 5 is a sectional view typically showing three pixel portions in the imaging device according to the embodiment. A structure of each pixel portion 1 of the imaging device according to the embodiment is the same as that of the pixel portion 1 of the imaging device in FIG. 1A. More specifically, a source 111S and a drain 111D in a transistor Tr are formed on a P well 111a of a semiconductor substrate 111. The source 111S and the drain 111D region are formed by an N type impurity ion implantation or thermal diffusion having a high doping concentration, and the source 111S is grounded. A gate oxide film 113 is provided above the semiconductor substrate 111 and an FG1, an FG2 and an FG3 to be electrically floating electrodes are provided on the gate oxide film 113. Moreover, an insulating layer 115 is provided above a part of the FG1, the FG2 and the FG3 and a CG1, a CG2 and a CG3 functioning as gates of the transistor Tr are provided on the insulating layer 115. The FG1, the FG2 and the FG3 are directly connected to pixel electrodes 116 through contact vias 114 functioning as wiring portions. The pixel electrodes 116 are provided in the pixel portion 1, respectively. Furthermore, the imaging device includes a transparent counter electrode 118 provided above the pixel electrode 116 and a photoelectric converting film 120 provided between the pixel electrode 116 and the transparent counter electrode 118, and the FG of the pixel portion 1 is electrically connected to the photoelectric converting film 120. A transparent protective film 122 is provided on the transparent counter electrode 118. A negative bias voltage is controllably applied to the transparent counter electrode 118.

The imaging device according to the embodiment has a structure in which a color filter CF is provided on the protective film 122 and can acquire a color imaging signal. For the photoelectric converting film 120, for example, there is used an amorphous silicon film, a panchromatic organic photoelectric converting film having a sensitivity over a whole visible light region or a CIGS (CuInGaSe) film.

The color filter CF has a function for transmitting mainly a light having a predetermined wavelength through each pixel portion 1 and causing the photoelectric converting film 120 provided therebelow to receive the light. In the embodiment, the color filter CF is constituted by an R filter (indicated as “R” in FIG. 5) for transmitting mainly a light having a red wavelength, a G filter (indicated as “G” in FIG. 5) for transmitting mainly a light having a green wavelength and a B filter (indicated as “B” in FIG. 5) for transmitting mainly a light having a blue wavelength in the incident lights. The respective filters are arranged in predetermined color patterns (for example, a Bayer color filter arrangement) over a plane on which the light is incident.

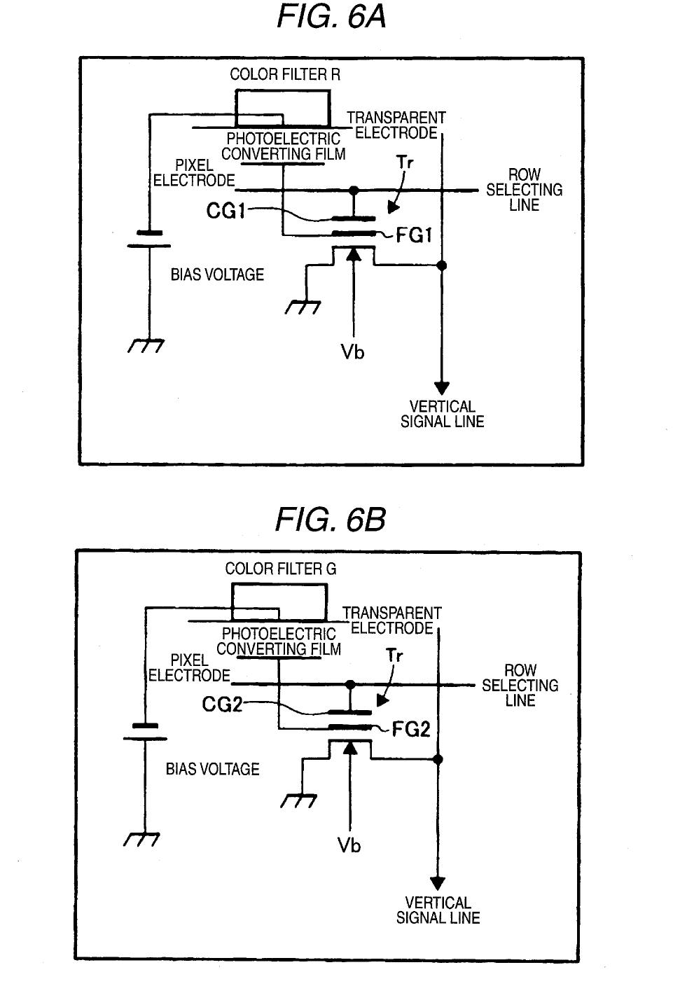

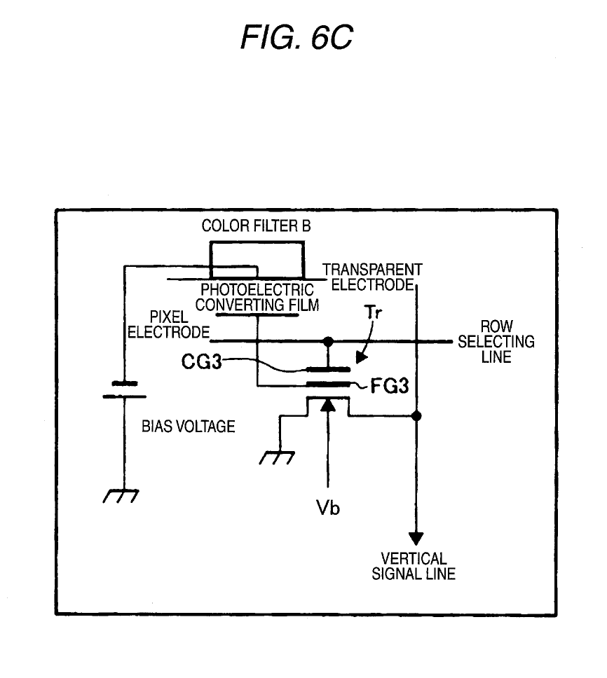

FIGS. 6A-6C are circuit diagrams showing each pixel portion of the imaging device according to the embodiment, and FIG. 6A is a circuit diagram showing the pixel portion for outputting a red color signal, FIG. 6B is a circuit diagram showing the pixel portion for outputting a green color signal, and FIG. 6C is a circuit diagram showing the pixel portion for outputting a blue color signal.

As shown in FIG. 6A, the pixel portion 1 having the R filter for transmitting the red wavelength includes the FG1 for changing an electric potential depending on a quantity of a charge generated in the photoelectric converting film 120 and the CG1 for changing a threshold voltage corresponding to the electric potential of the FG1. A threshold voltage of the transistor Tr is detected and a red color imaging signal is output.

As shown in FIG. 6B, the pixel portion 1 having the G filter for transmitting the green wavelength includes the FG2 for changing an electric potential depending on the quantity of the charge generated in the photoelectric converting film 120 and the CG2 for changing a threshold voltage corresponding to the electric potential of the FG2. The threshold voltage of the transistor Tr is detected and a green color imaging signal is output.

As shown in FIG. 6C, the pixel portion 1 having the B filter for transmitting the blue wavelength includes the FG3 for changing an electric potential depending on the quantity of the charge generated in the photoelectric converting film 120 and the CG3 for changing a threshold voltage corresponding to the electric potential of the FG3. The threshold voltage of the transistor Tr is detected and a blue color imaging signal is output.

In the same manner as the imaging device in FIGS. 1A and 1B, the imaging device according to the embodiment has a structure in which the charge generated in the photoelectric converting film 120 is transmitted to the FG and a signal corresponding to a change in the electric potential of the FG is output. It is not necessary to form a pn junction photodiode in the semiconductor substrate 111. Therefore, the imaging device is rarely influenced by a reduction in a sensitivity with an enhancement in a fineness of the pixel portion 1 and can carry out an imaging operation with a high sensitivity.

Moreover, there is employed the method of reading the charge generated in the photoelectric converting film 120 onto the FG, and it is not necessary to provide an impurity layer having a high concentration for taking an ohmic contact in the surface portion of the semiconductor substrate 111. Therefore, it is possible to relieve a deterioration in picture quality which is caused by a dark current noise.

According to the structure of the imaging device in accordance with the embodiment, furthermore, it is possible to reduce a capacitive image lag.

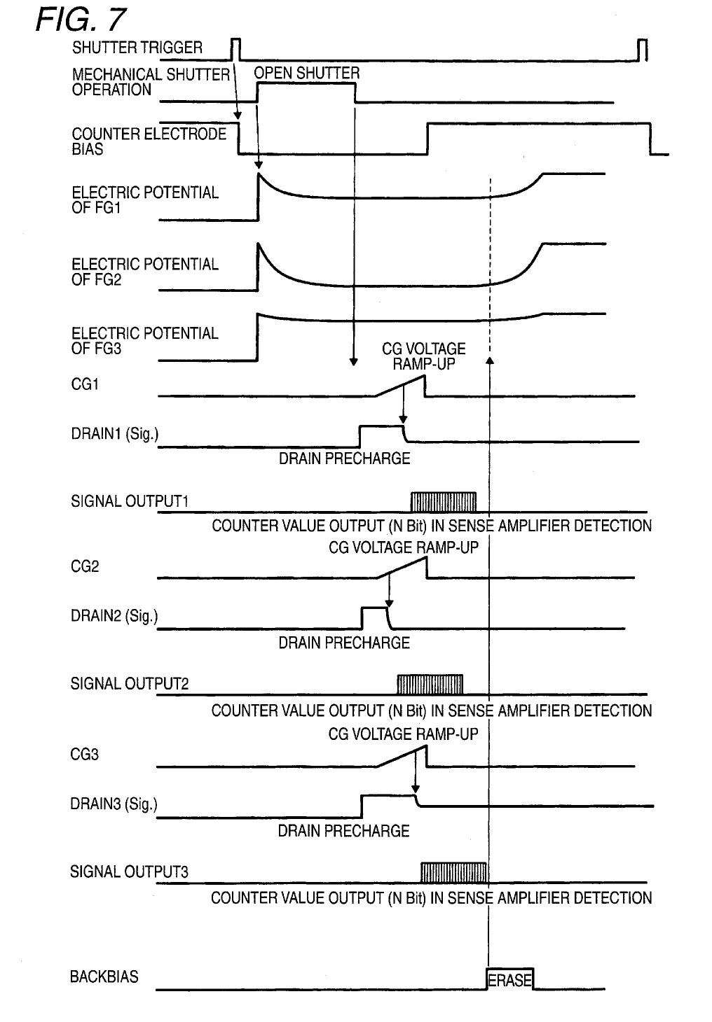

Next, description will be given to an operation of the imaging device according to the embodiment. FIG. 7 is a timing chart showing the case in which the still image pickup is carried out by the imaging device.

When imaging condition setting (AE or AF) for the still image pickup is previously carried out and the still image pickup operation (for fully pressing a shutter button) is executed, a shutter trigger rises so that the still image pickup is started on the set imaging condition.

When the shutter trigger rises, a bias voltage of the transparent counter electrode 118 is set to have a low level so that the quantity of the charge or the change in the electric potential generated in the photoelectric converting film 120 can be transmitted to the FG1, the FG2 and the FG3 in each of the pixel portions 1. When a timing for starting an exposure period is set after the shutter trigger rises, a mechanical shutter is opened and is maintained to be opened till a timing for ending the exposure period.

When the mechanical shutter is opened, a light transmitted through the color filter CF is incident on the photoelectric converting film 120 and the charge is generated by the light which is incident on the photoelectric converting film 120. By the charge generated in the photoelectric converting film 120, the electric potentials of the FG1, the FG2 and FG3 are changed.

Before the mechanical shutter is closed, a drain voltage is applied to the drain 111D of each of the pixel portions 1 and the drain 111D is precharged. “Drain1 (Sig.)”, “Drain2 (Sig.)” and “Drain3 (Sig.)” shown in FIG. 7 correspond to the drains 111D of the pixel portions 1 for detecting the red, green and blue colors respectively, and indicate changes in the electric potentials of the respective drains 111D.

When the voltages of the CG1, the CG2 and the CG3 in each of the pixel portions 1 in a first line are ramped up so that the channel region of the transistor Tr is conducted, next, the electric potential of the drain 111D is dropped. The sense amplifier detects, as counter values, the values of the CG1, the CG2 and the CG3 which are obtained when the electric potential of the drain 111D is dropped, and outputs the counter values as N-bit imaging signals. “Signal Output1”, “Signal Output2” and “Signal OUtput3” shown in FIG. 7 indicate a red color imaging signal, a green color imaging signal and a blue color imaging signal, respectively.

Referring to each of the pixel portions 1 after a second line, similarly, the ramp-up operation for each of gate voltages in the CG1, the CG2 and the CG3 is sequentially carried out and an imaging signal is sequentially output from each line.

When the imaging signals are output from all of the pixel portions 1 so that the still image pickup is ended, the charges stored in the FG1, the FG2 and the FG3 in each of the pixel portions 1 to prepare for next still image pickup are batch erased. Examples of a method of batch erasing the charges include a method of applying a negative voltage to the CG1, the CG2 and the CG3 and applying a positive voltage to the semiconductor substrate 111, thereby extracting and discharging the charges stored in the FG1, the FG2 and the FG3 to the semiconductor substrate 111 side respectively. “BackBias” shown in FIG. 7 indicates a change in a back bias voltage to be applied when batch erasing the charges.

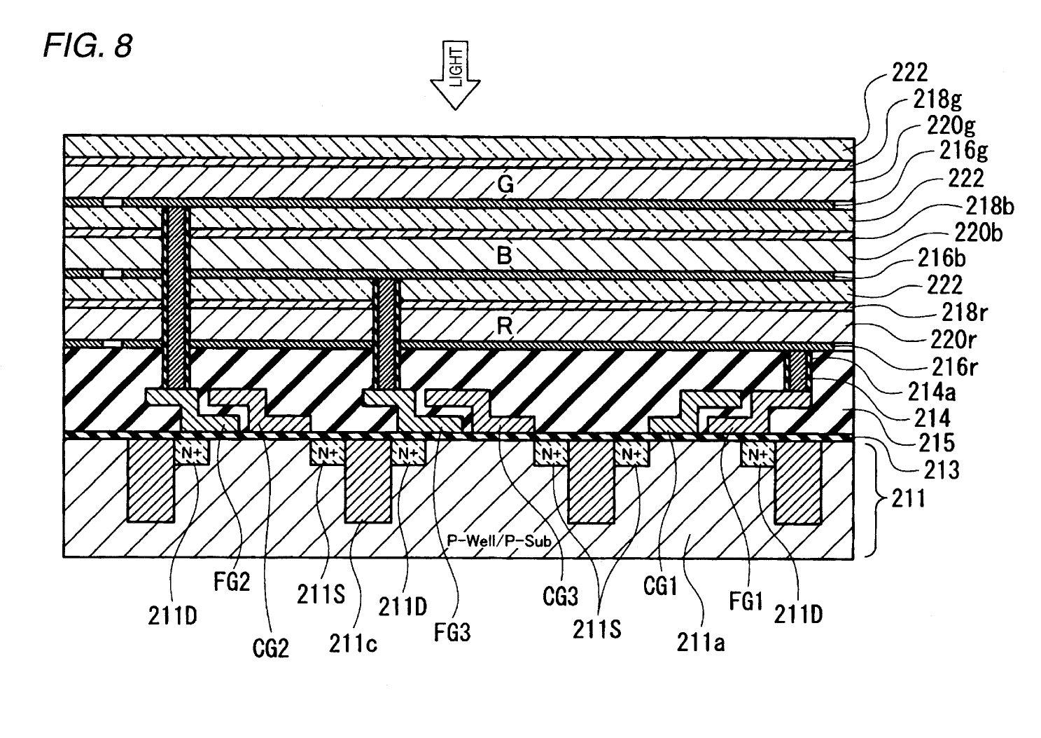

Next, description will be given to yet another embodiment of the imaging device. FIG. 8 is a sectional view typically showing three pixel portions in the imaging device according to the embodiment. A structure of each pixel portion 1 of the imaging device according to the embodiment is the same as that of the pixel portion 1 of the imaging device in FIG. 1A. More specifically, a source 211S and a drain 211D in a transistor Tr are formed on a P well 211a of a semiconductor substrate 211 through an N+ type impurity diffusion region having a high concentration, and the source 211S is grounded. A gate oxide film 213 is provided on the semiconductor substrate 211 and an FG1, an FG2 and an FG3 to be electrically floating electrodes are provided above the gate oxide film 213. Moreover, an insulating layer 215 is provided on a part of the FG1, the FG2 and the FG3, and a CG1, a CG2 and a CG3 functioning as gates of the transistor Tr are provided above the insulating layer 215.

In the imaging device according to the embodiment, a pixel electrode 216r is provide on the insulating layer 215, a photoelectric converting portion 220r having a sensitivity to at least a light having a red wavelength is provided on the pixel electrode 216r, and a transparent counter electrode 218r is provided on the photoelectric converting portion 220r.

Moreover, a transparent protective film 222 is provided on the transparent counter electrode 218r, a pixel electrode 216b is provided on the transparent protective film 222, and a photoelectric converting portion 220b having a sensitivity to mainly a light having a blue wavelength and a transparent counter electrode 218b are stacked on the pixel electrode 216b in order.

Furthermore, the transparent protective film 222 is provided on the transparent counter electrode 218b, a pixel electrode 216g is provided on the transparent protective film 222, and a photoelectric converting portion 220g having a sensitivity to only a light having a green wavelength, a transparent counter electrode 218g and the transparent protective film 222 are stacked on the pixel electrode 216g in order.

Contact vias 214 are connected to the pixel electrodes 216r, 216g and 216b, respectively. The pixel electrode 216r is connected to the FG1 through the contact via 214, the pixel electrode 216g is connected to the FG2 through the contact via 214, and the pixel electrode 216b is connected to the FG3 through the contact via 214. The contact via 214 to be connected to the pixel electrode 216g is provided to penetrate the photoelectric converting films 220r and 220b, the pixel electrodes 216r and 216b, and the transparent counter electrodes 218r and 218b. The contact via 214 to be connected to the pixel electrode 216b is provided to penetrate the photoelectric converting film 220r, the pixel electrode 216r and the transparent counter electrode 218r. A side surface of each contact via 214 is covered with an insulating film 214a and is electrically insulated from members other than the pixel electrode connected to read charges. A negative voltage is controllably applied to each of the pixel electrodes 216r, 216g and 216b.

In the embodiment, the contact via 214 and portions of the FG1, the FG2 and the FG3 which are provided in contact with the contact via 214 should be positioned on a device isolation region 211c or on the FG1, the FG2 and the FG3 extended over the thick insulating layer 215 provided on the gate oxide film 213. Thus, it is possible to separate positions of the contact via 214 and the portions of the FG1, the FG2 and the FG3 which are provided in contact with the contact via 214 from the transistor Tr. Consequently, it is possible to avoid a fluctuation in an electric potential of the semiconductor substrate 211 or the P well 211a due to a fluctuation in the electric potentials of the FG1, the FG2 and the FG3.

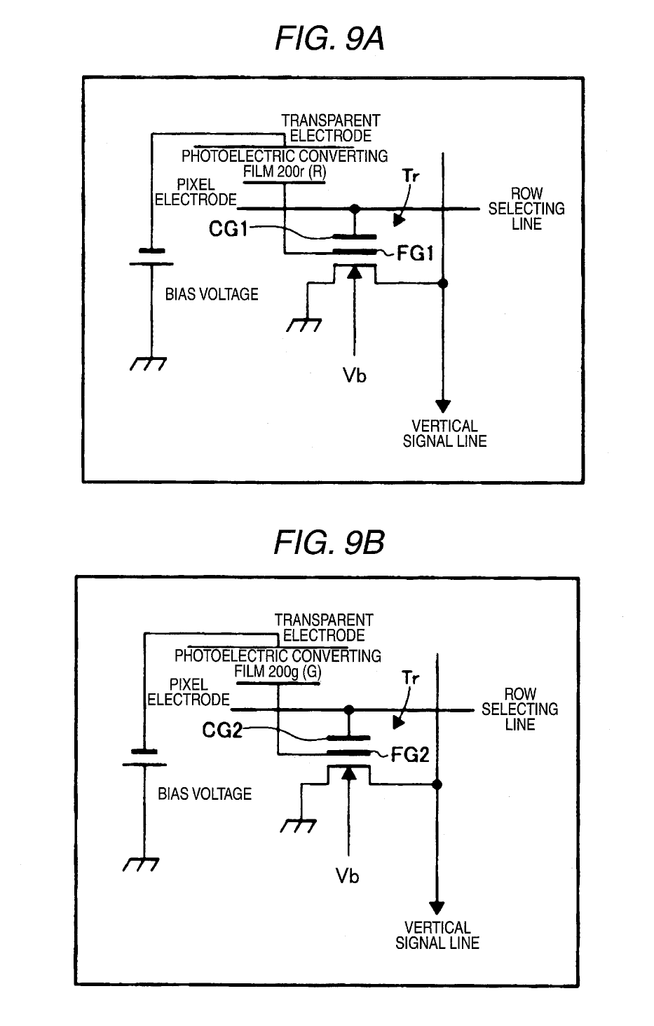

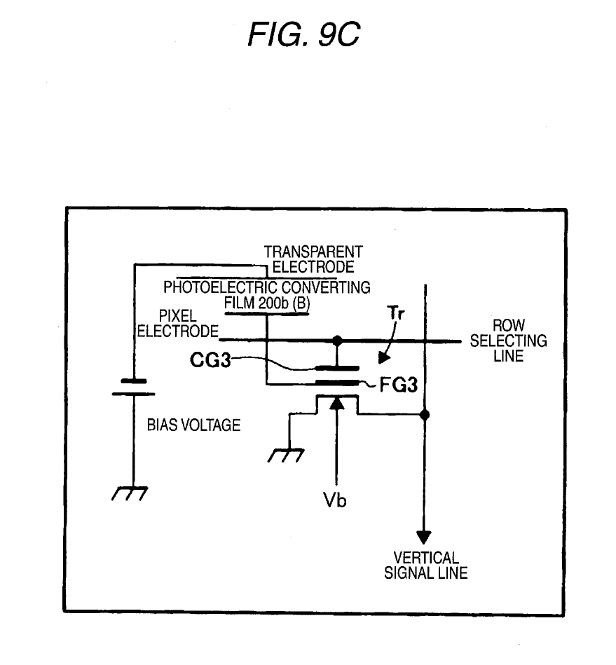

FIGS. 9A to 9C are circuit diagrams showing each pixel portion of the imaging device according to the embodiment, and FIG. 9A is a circuit diagram showing the pixel portion for outputting a red color signal, FIG. 9B is a circuit diagram showing the pixel portion for outputting a green color signal, and FIG. 9C is a circuit diagram showing the pixel portion for outputting a blue color signal.

In the photoelectric converting film 220r of the pixel portion 1 shown in FIG. 9A, a light having a red wavelength which is not absorbed by the photoelectric converting films 220g and 220b but is transmitted is detected and a charge is generated by a photoelectric conversion. The pixel portion 1 includes the FG1 for changing an electric potential depending on a quantity of the charge generated in the photoelectric converting portion 220r and the control gate electrode CG1 of the transistor Tr, and detects a threshold voltage of the transitor Tr, depending on the electric potential of the FG1 with respect to a change in a drain current of the transistor Tr and outputs a red color imaging signal.

In the photoelectric converting film 220g of the pixel portion 1 shown in FIG. 9B, any of lights which is incident on the imaging device and has a wavelength other than the green wavelength is transmitted and a charge is generated by a photoelectric conversion by receiving the light having the green wavelength. The pixel portion 1 includes the FG2 for changing the electric potential depending on a quantity of the charge generated in the photoelectric converting portion 220g and the CG2 taking the gate of the transistor Tr, and detects a threshold voltage based on the electric potential of the CG2 with respect to the change in the drain current of the transistor Tr and outputs a green color imaging signal.

In the photoelectric converting film 220b of the pixel portion 1 shown in FIG. 9C, any of lights which is transmitted through the photoelectric converting film 220g and has a blue wavelength is detected and a charge is generated by the photoelectric conversion. The pixel portion 1 includes the FG3 for changing the electric potential corresponding to the charge generated in the photoelectric converting portion 220b and the CG3 taking the gate of the transistor Tr, and detects a threshold voltage based on the electric potential of the CG3 with respect to the change in the drain current of the transistor Tr and outputs a blue color imaging signal. A structure of the transistor Tr is the same as that described in the structure of the imaging device in FIG. 1A.

The imaging device according to the embodiment has a structure in which the charges generated in the photoelectric converting films 220r, 220g and 220b having different spectral characteristics from each other are transmitted to the FG1, the FG2 and the FG3 respectively, and signals corresponding to a change in the electric potentials of the FG1, the FG2 and the FG3 are output. Thus, it is not necessary to form a pn junction photodiode in the semiconductor substrate 211. Therefore, the imaging device is rarely influenced by a reduction in a sensitivity with an enhancement in a fineness of the pixel portion 1 and can carry out an imaging operation with a high sensitivity.

Moreover, there is employed the method of reading the charges generated in the photoelectric converting films 220r, 220g and 220b onto the FG1, the FG2 and the FG3 through the contact via 214 respectively, and it is not necessary to provide an impurity diffusion region having a high concentration for taking an ohmic contact in the surface portion of the semiconductor substrate 211. Therefore, it is possible to relieve a deterioration in picture quality which is caused by a dark current noise.

Moreover, a color filter is not required in the imaging device according to the embodiment. Therefore, it is possible to avoid a deterioration in picture quality which is caused by a generation of a leakage of a light to the adjacent pixel portion.

The operation of the imaging device according to the embodiment can output a signal in the same manner as the operation of the imaging device shown in FIG. 7.

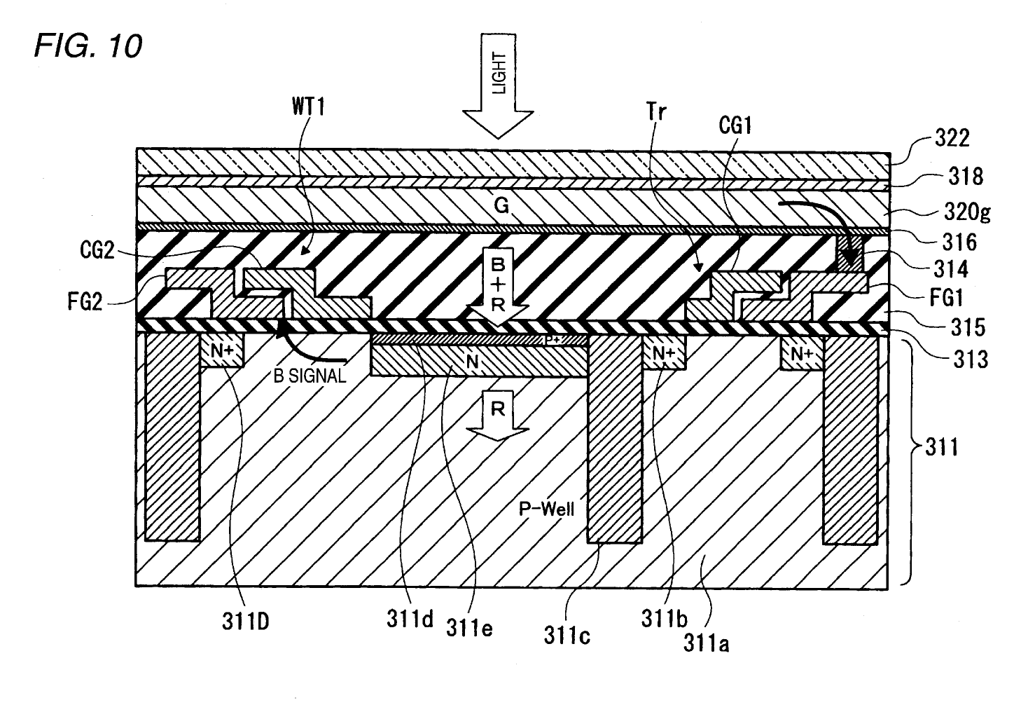

Next, description will be given to a further embodiment of the imaging device. FIG. 10 is a sectional view typically showing a single pixel portion of the imaging device. In the imaging device according to the embodiment, a contact via 314 is connected to pixel electrode 316 which is provided below a photoelectric converting film 320g. A lower end portion of the contact via 314 is connected to an FG1. The imaging device includes a transistor Tr using, as a gate, a CG1 for changing an threshold voltage in a flow of a drain current when an electric potential of the FG1 changes.

Moreover, a P+ type impurity diffusion region 311d having a high concentration and an N type impurity diffusion region 311e are formed on a surface of a semiconductor substrate 311. The N type impurity diffusion region 311e is provided under the impurity diffusion region 311d and functions as a pn junction berried photodiode PD.

The imaging device according to the embodiment includes a writing transistor WT1 for temporarily storing a charge generated in the photodiode PD. An FG2 floating electrically by the gate oxide film 313 is provided above a channel region of the semiconductor substrate 311 and an electric potential controllable CG2 is provided to read a charge stored in the FG2. In the writing transistor WT1, the CG2 is set to be a gate, the photodiode PD is set to be a source, and an N+ type impurity diffusion region 311D having a high concentration which is disposed at an interval from the PD on a surface of the semiconductor substrate 311 is set to be a drain. A channel region is formed on a surface of the semiconductor substrate 311 between the PD and the impurity diffusion region 311D.

In the embodiment, the single transistor Tr and the single writing transistor WT1 are provided in each pixel portion 1, and a device isolation region 311c is formed between the transistor Tr and the writing transistor WT1.

The transistor Tr has a source 311S and the drain 311D which are formed by an N type impurity ion implantation or thermal diffusion region having a high doping concentration in a P well 311a of the semiconductor substrate 311. Moreover, the gate oxide film 313 is provided on the P well 311a and the FG1 is provided on the gate oxide film 313. An insulating layer 315 is provided on the FG1 and the CG1 functioning as the gate of the transistor Tr is provided above an insulating layer 315.

The FG1 is electrically connected to the pixel electrode 316 through the contact via 314. The photoelectric converting film 320g having a sensitivity to mainly a light having a green wavelength is provided on the pixel electrode 316. A transparent counter electrode 318 is formed on the photoelectric converting film 320g and a surface of the transparent counter electrode 318 is covered with a transparent protective film 322. The contact via 314 and a portion in the FG1 which is provided in contact with the contact via 314 should be formed on the device isolation region 311c. Since an operation of the transistor Tr is the same as that in the embodiment, description will be omitted.

The photodiode PD is formed in the vicinity of the writing transistor WT1. The photodiode PD is constituted by the P+ type impurity diffusion region 311d having a high concentration which is formed on a surface of the P well 311a and the N type impurity diffusion region 311e formed under the impurity diffusion region 311d. The photodiode PD constitutes a source of the writing transistor WT1. In the embodiment, the photodiode PD is distributed and formed shallowly to mainly enable an efficient absorption of a light having a blue wavelength with respect to a vertical direction from the surface of the semiconductor substrate 311.

The imaging device shown in FIG. 10 detects a G component in primary color components (R, G, B) contained in an incident light through the photoelectric converting film 320g provided over all of the pixel portions, and outputs a G signal. Thus, it is possible to output the G signal from all of the pixel portions (sampling points). By causing the G signal to contribute to a luminance signal component, it is possible to enhance a resolution.

In the same pixel portion (sampling) position, moreover, a signal charge corresponding to a light having a blue wavelength is detected by the PD provided in the semiconductor substrate 311. Consequently, it is possible to reduce a color mixture of the respective color components.

Since the structure does not require the color filter, furthermore, it can utilize an incident light more effectively with a higher resolution as compared with a structure in which a filter corresponding to each of the pixel portions is arranged mosaically, and is suitable for an image sensor having a high sensitivity.

The structures of the FG2 and the CG2 in the writing transistor WT1 can be formed of the same doped polysilicon as that in the FG1 and the CG1 in the transistor Tr.

The imaging device according to the embodiment can carry out an operation for writing a signal by injection, into the FG2 of the transistor WT1, a charge (a B signal) corresponding to the light having the blue wavelength which is generated in the photodiode PD.

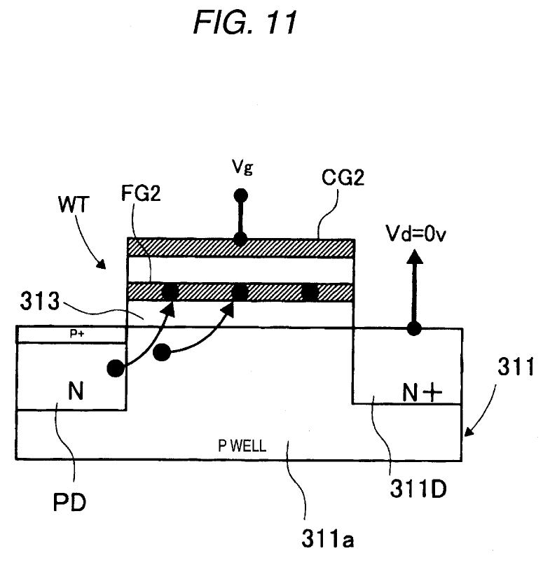

FIG. 11 is a typical sectional view showing a writing transistor, illustrating a principle of a writing operation of the writing transistor according to the embodiment and explaining a state in which a charge is trapped.

As shown in FIG. 11, a charge is generated when a light is incident on the photodiode PD, and an electric potential of a channel region is controlled by the CG2. Consequently, the charge stored in the photodiode PD of the P well 311a is injected into the FG beyond or through the gate oxide film 313.

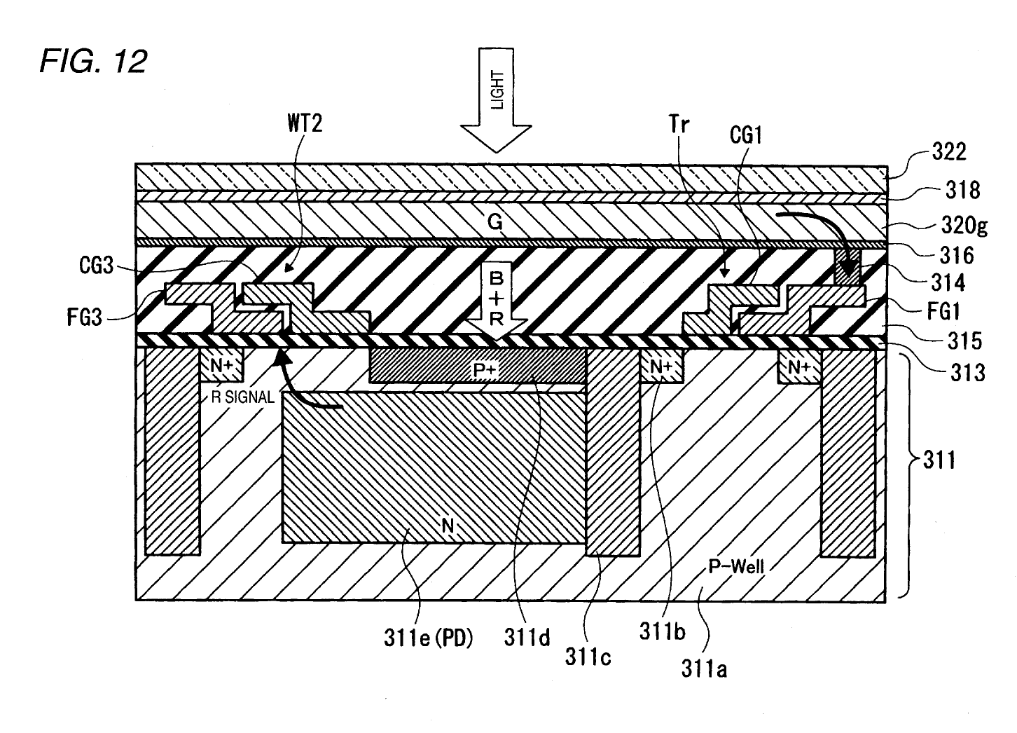

FIG. 12 is a sectional view typically showing another pixel portion of the imaging device according to the embodiment. A basic structure of the imaging device is the same as that of the pixel portion of the imaging device shown in FIG. 10. On the other hand, in each pixel portion of the imaging device shown in FIG. 12, the N type impurity diffusion region 311e is further formed under the P+ type impurity diffusion region 311d having a high concentration. The P well 311a and the impurity diffusion region 311e constitute the pn junction photodiode PD, and the photodiode PD is distributed and formed deeply in the P well 311a of the semiconductor substrate 311 to mainly have a sensitivity to a light having a red wavelength.

As shown in FIGS. 10 and 12, thus, the imaging device according to the embodiment has a structure in which each pixel portion detects a G signal corresponding to a light having a green wavelength through the photoelectric converting film 320g, a part of all the pixel portions 1 detect a B signal through the photodiode PD in the semiconductor substrate 311, and the residual pixel portions 1 detect an R signal through the photodiode PD in the semiconductor substrate 311.

As shown in FIG. 12, the charge (R signal) generated in the photodiode PD is injected into an FG3 of a writing transistor WT2 and can be read by an application of a reading pulse to a CG3 for a reading period.

By reading the charge generated in the photoelectric converting film 320g provided to cover all of the pixel portions through the transistor Tr, moreover, it is possible to output the G signal from all of the pixel portions (sampling points) and to enhance a resolution by causing the G signal to contribute to a luminance signal component.

The imaging device according to the embodiment can detect the R, G and B signals for generating a color image by alternately pattern arranging the pixel portion 1 for detecting the G and B signals and the pixel portion 1 for detecting the G and R signals in a light receiving region.

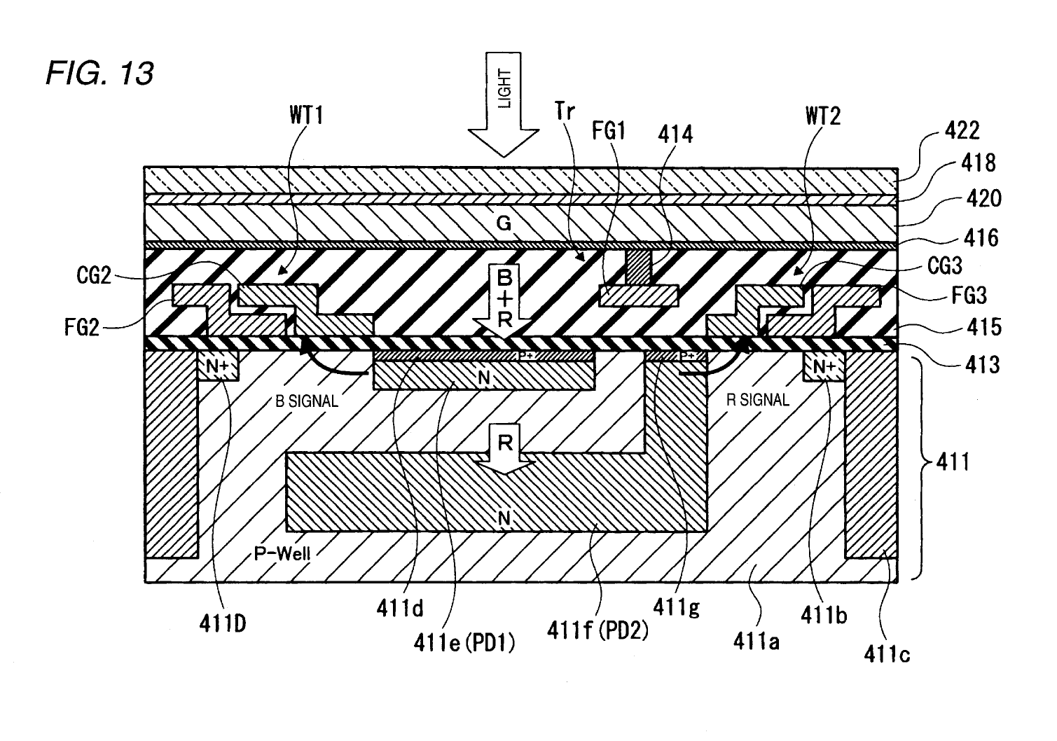

Next, description will be given to a further embodiment of the imaging device. FIG. 13 is a sectional view typically showing a single pixel portion of the imaging device. A basic structure of the imaging device according to the embodiment is the same as the structures of the imaging devices shown in FIGS. 10 and 12. The imaging device according to the embodiment has a structure in which a first photodiode PD1 and a second photodiode PD2 having different positions in a vertical direction from a surface on a light incident side are multiplexed and provided on a P well 411a of a semiconductor substrate 411 in each pixel portion 1.

A P+ type impurity diffusion region 411d having a high concentration and an N type impurity diffusion region 411e are provided in the semiconductor substrate 411 of each pixel portion 1. The P+ type impurity diffusion region 411d having a high concentration is provided on a surface of the P well 411a. The N type impurity diffusion region 411e is formed under the P+ type impurity diffusion region 411d and functions as the first photodiode PD1. The first photodiode PD1 has a sensitivity to a light having a blue wavelength.

Moreover, an N type impurity diffusion region 411f is formed in the P well 411a provided under the first photodiode PD1, and a part of the N type impurity diffusion region 411f is distributed to the vicinity of a surface of the semiconductor substrate 411 and a P+ type impurity diffusion region 411g having a high concentration is formed thereon. The N type impurity diffusion region 411f constitutes the second photodiode PD2 having a sensitivity to a light having a red wavelength.

An FG2 for storing a charge generated in the first photodiode PD1 and an FG3 for storing a charge generated in the second photodiode PD2 are provided on a gate oxide film 413 formed on the surface of the semiconductor substrate 411.

Moreover, a photoelectric converting film 420 provided above the semiconductor substrate 411 has a sensitivity to a light having a green wavelength. A pixel electrode 416 is provided under the photoelectric converting film 420 and is electrically connected to an FG1 through a contact via 414. Moreover, there is provided a control gate (which is indicated as a CG1 in the embodiment) for changing a threshold voltage so as to start to increase a drain current when an electric potential of the FG1 changes.

A transistor Tr having the FG1 has an MOS type structure in which the CG1 is used as a gate electrode. Description will be omitted in the embodiment because structures of a source and a drain are the same as the structures and operations according to the respective embodiments, which are not shown.

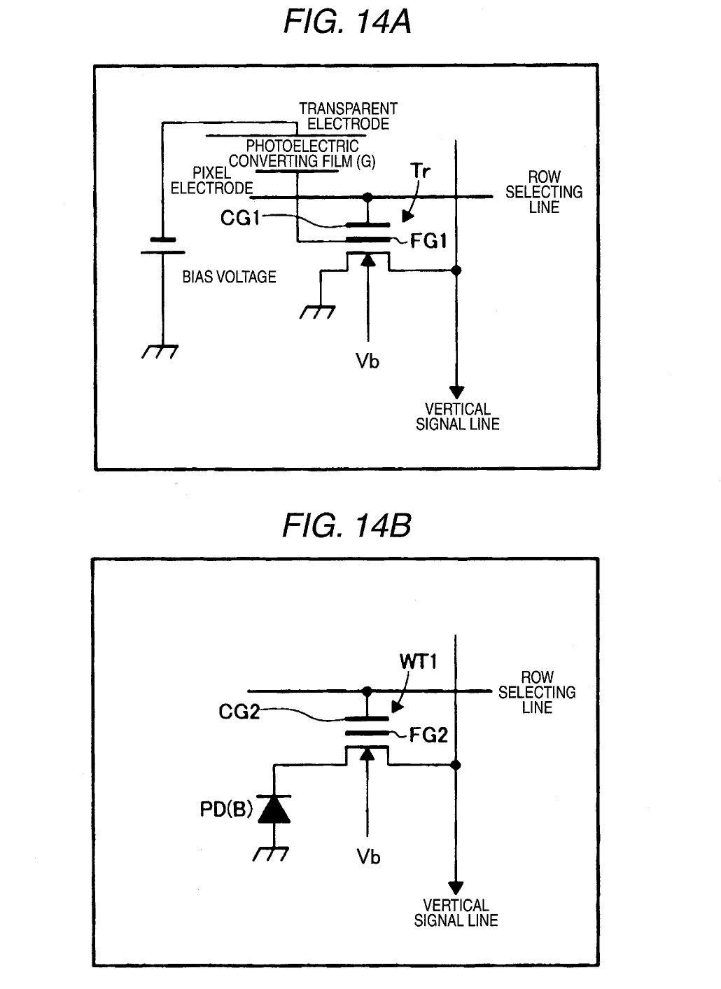

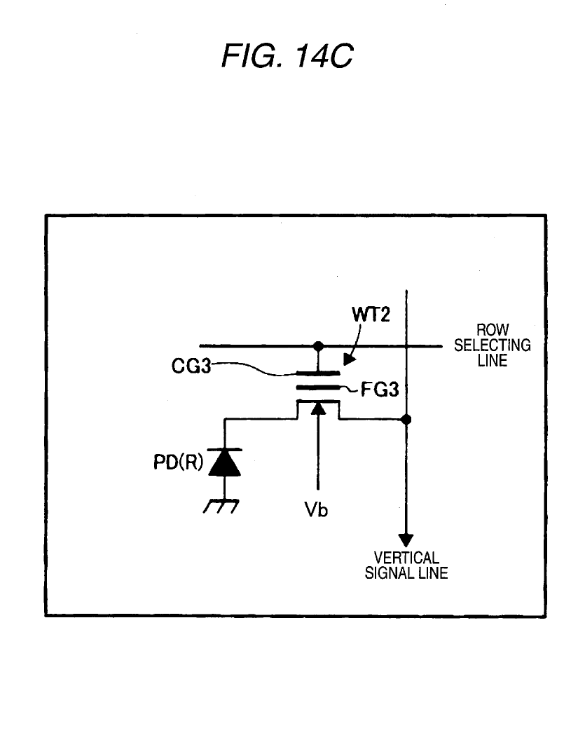

FIGS. 14A to 14C are circuit diagrams showing each pixel portion of the imaging device, and FIG. 14A is a circuit diagram for outputting a green color signal, FIG. 14B is a circuit diagram for outputting a blue color signal and FIG. 14C is a circuit diagram for outputting a red color signal.

As shown in FIG. 14A, mainly a light having a green wavelength is detected and a charge is generated by a photoelectric conversion in a photoelectric converting film of the pixel portion 1. The pixel portion 1 has the FG1 for changing an electric potential depending on the quantity of the charge generated in the photoelectric converting film and the CG1 for changing the threshold voltage so as to start to increase a drain current when the electric potential of the FG1 changes, and detects a threshold voltage of a transistor Tr and outputs a green color imaging signal.

As shown in FIG. 14B, there is provided a first writing transistor WT1 for detecting a light having a blue wavelength by the first photodiode PD1 and generating a signal charge, and changing an electric potential of the FG2 depending on the quantity of the generated charge. The first writing transistor WT1 has a source provided with the first photodiode PD1 and has a drain provided with an N+ type impurity diffusion region 411D having a high concentration which is to be connected to a vertical signal line. A CG2 is connected as a gate of the first writing transistor WT1 to a row selecting line. A writing pulse is applied to the CG2 so that the charge of the first photodiode PD1 is injected into the FG2. Thus, it is possible to write a G signal to the first writing transistor WT1. In a reading operation, in the same manner as the transistor Tr1, a ramp-up operation for a gate voltage of the CG2 is carried out to detect a threshold voltage so as to start to increase a drain current when the electric potential of the FG2 changes and to output a blue color imaging signal.

As shown in FIG. 14C, there is provided a second writing transistor WT2 for detecting a light having a red wavelength by the second photodiode PD2 and generating a signal charge, and changing an electric potential of the FG3 corresponding to the generated charge. The second writing transistor WT2 has a source provided with the second photodiode PD2 and has a drain provided with the N+ type impurity diffusion region 411D having a high doping concentration which is to be connected to a vertical signal line. A CG3 is connected as a gate of the second writing transistor WT2 to a row selecting line. A writing pulse is applied to the CG3 so that the charge of the second photodiode PD2 is injected into the FG3. Thus, it is possible to write an R signal to the second writing transistor WT2. In a reading operation, a ramp-up operation for a gate voltage of the CG3 is carried out to detect a threshold voltage so as to start to increase a drain current when the electric potential of the FG3 changes and to output a red color imaging signal.

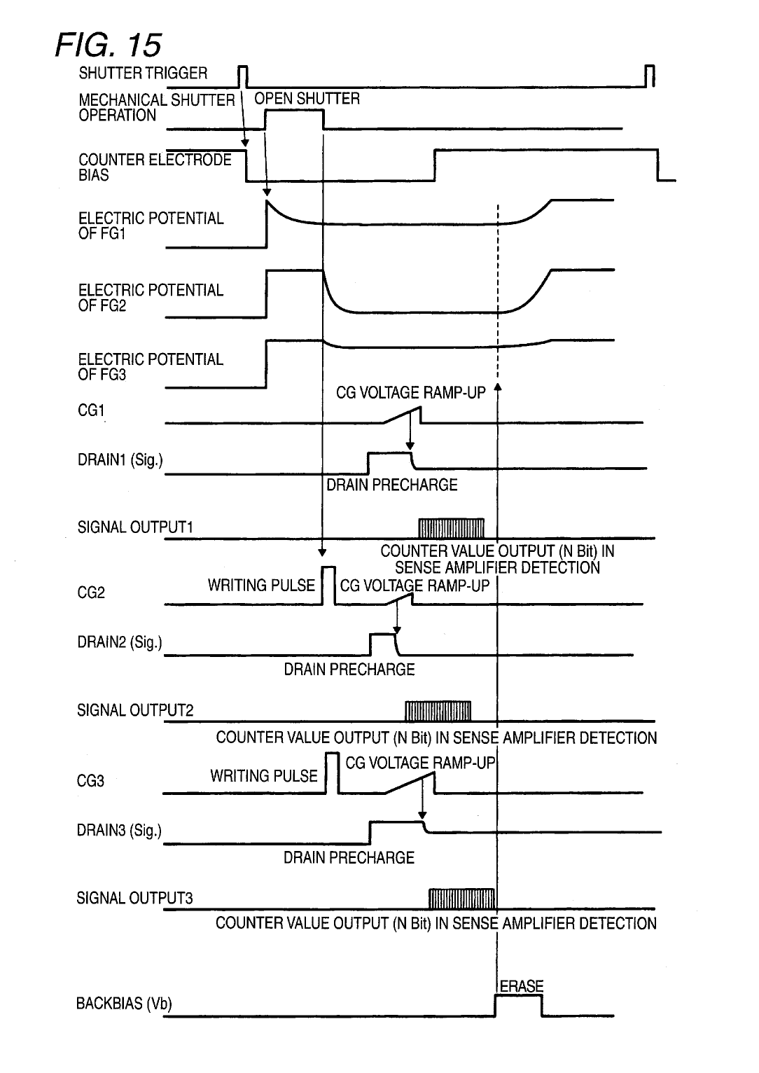

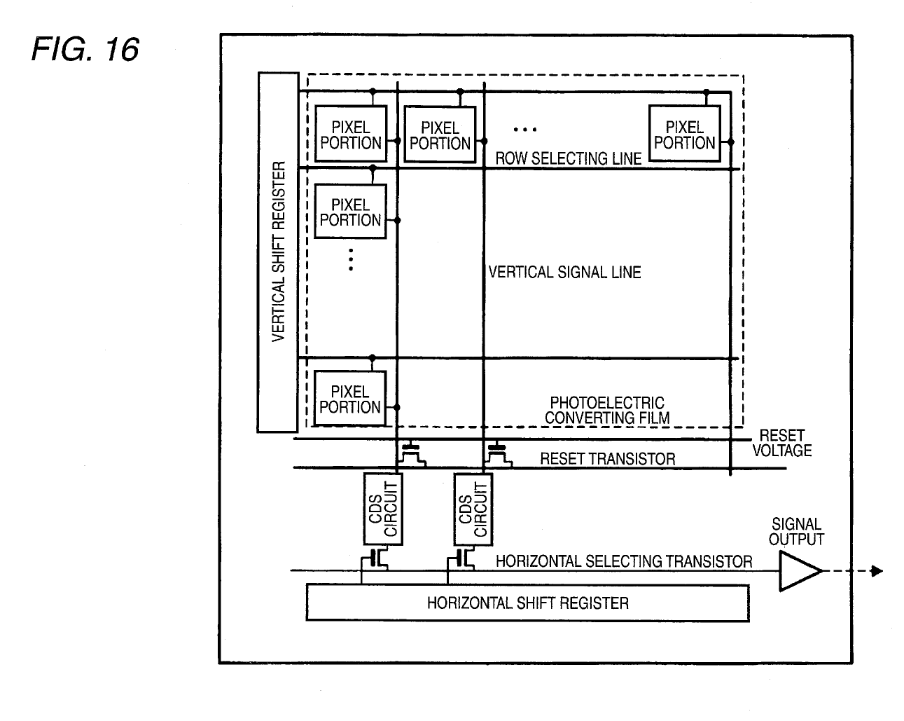

Next, description will be given to operations of the imaging devices shown in FIGS. 10 and 12 and the imaging device shown in FIG. 13. FIG. 15 is a timing chart showing the case in which a still image pickup operation is carried out by the imaging device.

When imaging condition setting (AE or AF) for the still image pickup is previously carried out and the still image pickup operation (for fully pressing a shutter button) is executed, a shutter trigger rises so that the still image pickup is started on the set imaging condition.

When the shutter trigger rises, a bias voltage of a transparent counter electrode 418 is set to have a low level so that a quantity of the charge or a change in the electric potential generated in the photoelectric converting film 420 can be transmitted to the FG1 of each pixel portion 1. When a timing for starting an exposure period is set after the shutter trigger rises, a mechanical shutter is opened and is maintained to be opened till a timing for ending the exposure period.

When the mechanical shutter is opened, a light transmitted through a color filter CF is incident on the photoelectric converting film 420 and the charge is generated depending on the light which is incident on the photoelectric converting film 420. By the charge generated in the photoelectric converting film 420, the electric potential of the FG1 is changed.

Next, there is executed a writing operation for applying a writing pulse to the CG2 of the first writing transistor WT1 and transmitting the charge generated in the first photodiode PD1 to the FG2. At the same time, a writing pulse is applied to the CG3 of the second writing transistor WT2 and the charge generated in the second photodiode PD2 is transmitted to the FG3.

A drain voltage is applied to the transistor Tr and the writing transistors WT1 and WT2 in each pixel portion 1 and they are precharged. “Drain1 (Sig.)”, “Drain2 (Sig.)” and “Drain3 (Sig.)” shown in FIG. 15 correspond to the drain of the transistor Tr for detecting a green color signal, the drain 411D of the transistor WT1 for detecting a blue color signal and the drain 411D of the transistor WT2 for detecting a red color signal respectively, and they indicate a change in electric potentials of the respective drains 411D.

Next, the voltages of the CG1, the CG2 and the CG3 in each of the pixel portions 1 in a first line are ramped up respectively and the channel regions of the transistor Tr and the writing transistors WT1 and WT2 are conducted so that the electric potential of the drain is dropped. The sense amplifier detects, based on a counter value, values of threshold voltages of the CG1, the CG2 and the CG3 which are obtained when the electric potential of the drain is dropped, and outputs the values as N-bit imaging signals, respectively. “Signal Output1”, “Signal Output2” and “Signal OUtput3” shown in FIG. 15 indicate a green color imaging signal, a blue color imaging signal and a red color imaging signal, respectively.

Referring to each of the pixel portions 1 after a second line, similarly, the signal charges of the photodiodes PD1 and PD2 are written to the FG2 and FG3 and the ramp-up operation for each of gate voltages in the CG1, the CG2 and the CG3 is then carried out sequentially, and an imaging signal is sequentially output from each line.

When the imaging signals are output from all of the pixel portions 1 so that the still image pickup is ended, the charges stored in the FG1, the FG2 and the FG3 in each of the pixel portions 1 to prepare for next still image pickup are batch erased. Examples of a method of batch erasing the charges include a method of applying a negative voltage to the CG1, the CG2 and the CG3 and applying a positive voltage to the semiconductor substrate 411, thereby extracting and discharging the charges stored in the FG1, the FG2 and the FG3 to the semiconductor substrate 411 side respectively. “BackBias (Vb)” shown in FIG. 15 indicates a change in a back bias voltage to be applied when batch erasing the charges.

By employing the structure in which the photodiodes PD1 and PD2 are provided in each of the pixel portions as shown in FIG. 13, it is possible to detect a light having a green wavelength through the photoelectric converting film 420 provided on the semiconductor substrate 411, to detect lights having red and blue wavelengths through the photodiodes PD1 and PD2 formed in the semiconductor substrate 411 in the same pixel position as the pixel portion for detecting the light having the green wavelength and to write the generated charge to the FG2 and the FG3. Thus, it is possible to acquire at least the R, G and B color signals in the same pixel (sampling) position, thereby reducing a mixed color or a false color which is apt to be generated between the adjacent pixel portions to each other.

There is employed the structure in which the photoelectric converting film 420 for covering all of the pixel portions in common is provided on the semiconductor substrate. Therefore, it is possible to avoid a reduction in a sensitivity with an enhancement in a fineness of the pixel. In addition, there is employed the structure in which the contact via to be electrically connected to the photoelectric converting film 420 is connected to the FG. Therefore, it is possible to prevent an occurrence of a dark current or a capacitive image lag without requiring to take an ohmic contact with the source or the drain on the surface of the semiconductor substrate.

Moreover, it is not necessary to provide a color filter. Therefore, the invention is suitable for an image sensor having a high resolution, high photo-electric conversion efficiency and a high sensitivity.

As described above, the specification has disclosed the following matters.

There has been disclosed an imaging device including a semiconductor substrate, a photoelectric converting film formed on the semiconductor substrate and generating a charge corresponding to an incident light, and a plurality of pixel portions, each of the pixel portions being provided with a floating gate which is electrically connected to the photoelectric converting film, and a transistor having a threshold voltage to fluctuate corresponding to an electric potential of the floating gate.

The imaging device has the structure in which the charge generated in the photoelectric converting film is transmitted to the floating gate and the signal corresponding to a change in the electric potential of the floating gate is output. It is not necessary to form a photodiode in the semiconductor substrate. Therefore, the imaging device is rarely influenced by a reduction in a sensitivity with an enhancement in a fineness of the pixel portion and can carry out an imaging operation having a high sensitivity.

The imaging device includes a control gate for reading a threshold voltage. Consequently, the threshold voltage read by the control gate can be output as a signal.

In the imaging device, a ramp-up operation for gradually increasing a voltage of the control gate or a ramp-down operation for gradually decreasing the voltage of the control gate is carried out and the threshold voltage obtained in a change in an electric potential of a FG of the transistor is output as a signal at that time. Consequently, it is possible to read, by a single transistor, a quantity of a charge stored in the floating gate by the ramp-up operation or the ramp-down operation for the voltage of the control gate. Therefore, it is possible to enhance a fineness of the pixel portion without requiring to provide a plurality of transistors in the pixel portion differently from a conventional CMOS image sensor.

In the imaging device, a device isolation region is formed between adjacent pixels to each other in the semiconductor substrate and at least a part of the floating gate is formed on the device isolating region. Consequently, the charge transmitted through the floating gate can be prevented from influencing the channel region of the transistor in the pixel portion.

The imaging device is provided with a wiring portion for electrically connecting the photoelectric converting film to the floating gate and transmitting a quantity of a charge or a change in an electric potential from the photoelectric converting film to the floating gate. Consequently, the quantity of the charge or the change in the electric potential corresponding to a quantity of a received light in the photoelectric converting film is transmitted to the floating gate through the wiring portion. Therefore, it is not necessary to cause a conductive member to take an ohmic contact with an impurity diffusion region having a high doping concentration over the surface of the semiconductor substrate.

In the imaging device, a device isolation region is formed between the adjacent pixel portions to each other in the semiconductor substrate and the wiring portion is formed on the device isolation region or the floating gate extended over an insulating film which is formed between the semiconductor substrate and the floating gate and is thicker than the other portions. Consequently, it is possible to avoid a fluctuation in an electric potential in the semiconductor substrate or a P well formed in the semiconductor substrate due to a fluctuation in an electric potential of the wiring portion.

In the imaging device, a color filter is formed on the photoelectric converting film. By outputting a signal charge corresponding to a light having a wavelength component transmitted through the color filter in an incident light by the pixel portion provided below the color filter, consequently, it is possible to generate a color image signal.

In the imaging device, a plurality of photoelectric converting layers having different spectral characteristics from each other is stacked on the semiconductor substrate. By outputting a signal through a transistor in the pixel portion corresponding to each photoelectric converting layer without providing the color filter, consequently, it is possible to generate a color image signal.

The imaging device includes a writing transistor having a photodiode formed below the photoelectric converting film in each of the pixel portions, a control gate using the photodiode as a source and capable of directly controlling an electric potential of a channel region, and a floating gate which isolates electrically over the channel region, and controlling an electric potential of the control gate to enable an injection of a charge into the floating gate. Consequently, it is possible to write a signal by generating the charge by receiving the light on the photodiode formed in the semiconductor substrate and temporarily holding the charge in the floating gate of the writing transistor. Moreover, the charge generated in the photoelectric converting film is separately read by the transistor. Therefore, it is possible to output, as signals, lights having different wavelength components from each other in the photoelectric converting film and the photodiode in each of the pixel portions.

In the imaging device, a plurality of photodiodes is provided in different depths from each other with respect to a surface of the semiconductor substrate. Consequently, it is possible to provide the photodiodes having different spectral characteristics from each other on the semiconductor substrate in each of the pixel portions. Thus, it is possible to output, as signals, lights having different wavelength components from each other in a single pixel portion.

Moreover, there has been disclosed a method of driving an imaging device including a semiconductor substrate, a photoelectric converting film formed above the semiconductor substrate and generating a charge corresponding to an incident light, and a plurality of pixel portions, each of the pixel portions being provided with a floating gate which is electrically connected to the photoelectric converting film, and a transistor having a threshold voltage to fluctuate corresponding to an electric potential of the floating gate, including the step of transmitting a quantity of the charge or a change in an electric potential from the photoelectric converting film to the floating gate and detecting a value of the threshold voltage fluctuating corresponding to the electric potential of the floating gate, thereby outputting a signal.

According to the method of driving an imaging device, there is employed the structure in which the charge generated in the photoelectric converting film is transmitted to the floating gate and the signal corresponding to a change in the electric potential of the floating gate is output. It is not necessary to form a photodiode in the semiconductor substrate. Therefore, the method is rarely influenced by a reduction in a sensitivity with an enhancement in a fineness of the pixel portion and can carry out an imaging operation having a high sensitivity.

The method of driving an imaging device reads the threshold voltage by a control gate. Consequently, the threshold voltage read by the control gate can be output as a signal.

In the method of driving an imaging device, a ramp-up operation for gradually increasing a voltage of the control gate or a ramp-down operation for gradually decreasing the voltage of the control gate is carried out and the threshold voltage obtained in a change in an electric potential of a drain of the transistor is output as a signal at that time. Consequently, it is possible to read, by a single transistor, a quantity of a charge stored in the floating gate by the ramp-up operation or the ramp-down operation for the voltage of the control gate. Therefore, it is possible to enhance a fineness of the pixel portion without requiring to provide a plurality of transistors in the pixel portion differently from a conventional CMOS image sensor.

In the method of driving an imaging device, a device isolation region is formed between adjacent pixels to each other in the semiconductor substrate and at least a part of the floating gate is formed on the device isolating region. Consequently, the charge transmitted through the floating gate can be prevented from influencing the channel region of the transistor in the pixel portion.

In the method of driving an imaging device, there is provided a wiring portion for electrically connecting the photoelectric converting film to the floating gate and transmitting the quantity of the charge or the change in the electric potential from the photoelectric converting film to the floating gate. Consequently, the quantity of the charge or the change in the electric potential corresponding to a quantity of a received light in the photoelectric converting film is transmitted to the floating gate by the wiring portion. Therefore, it is not necessary to cause a conductive member to take an ohmic contact with an impurity diffusion region having a high concentration over the surface of the semiconductor substrate.

In the method of driving an imaging device, a device isolation region is formed between the adjacent pixel portions to each other in the semiconductor substrate and the wiring portion is formed on the device isolation region or the floating gate extended over an insulating film which is formed between the semiconductor substrate and the floating gate and is thicker than the other portions. Consequently, it is possible to avoid a fluctuation in an electric potential in the semiconductor substrate or a P well formed in the semiconductor substrate due to a fluctuation in an electric potential of the wiring portion.

In the method of driving an imaging device, a color filter is formed on the photoelectric converting film. By outputting a signal charge corresponding to a light having a wavelength component transmitted through the color filter in an incident light by the pixel portion provided below the color filter, consequently, it is possible to generate a color image signal.

In the method of driving an imaging device, a plurality of photoelectric converting films having different spectral characteristics from each other is stacked on the semiconductor substrate. By outputting a signal through a transistor in the pixel portion corresponding to each of the photoelectric converting films without providing the color filter, consequently, it is possible to generate a color image signal.

In the method of driving an imaging device, each of the pixel portions is provided with a photodiode formed below the photoelectric converting film, a control gate using the photodiode as a source and capable of directly controlling an electric potential of a channel region, and a floating gate which floats electrically over the channel region, and an electric potential of the control gate is controlled to inject a charge into the floating gate, thereby carrying out an operation for writing a signal. Consequently, it is possible to write a signal by generating the charge by receiving the light on the photodiode formed in the semiconductor substrate and temporarily holding the charge in the floating gate of the writing transistor. Moreover, the charge generated in the photoelectric converting film is separately read by the transistor. Therefore, it is possible to output, as signals, lights having different wavelength components from each other in the photoelectric converting film and the photodiode respectively in each of the pixel portions.

In the method of driving an imaging device, a plurality of photodiodes is provided in different depths from each other with respect to a surface of the semiconductor substrate. Consequently, it is possible to provide the photodiodes having different spectral characteristics from each other on the semiconductor substrate in each of the pixel portions. Thus, it is possible to output, as signals, lights having different wavelength components from each other in a single pixel portion.

Furthermore, an imaging apparatus including the imaging device is rarely influenced by a reduction in a sensitivity with an enhancement in a fineness of the pixel portion and can carry out an imaging operation having a high sensitivity.

What is claimed is:

1. An imaging device comprising:
a semiconductor substrate;
a photoelectric converting film on the semiconductor substrate, generating charges according to incident light; and
a plurality of pixel portions that receive the charges from the photoelectric converting film,
wherein each of the pixel portions includes:
a floating gate that is electrically connected to the photoelectric converting film; and
a transistor that has a threshold voltage to fluctuate according to an electric potential of the floating gate.

2. The imaging device according to claim 1, further comprising:
a control gate that reads the threshold voltage.

3. The imaging device according to claim 2, further comprising:
a rump-up circuit that carries out a rump-up operation for gradually increasing a voltage of the control gate, or a rump-down circuit that carries out a ramp-down operation for gradually decreasing the voltage of the control gate,
wherein the threshold voltage as of a moment of change in an electric potential of a drain of the transistor is output as a signal in the rump-up or rump-down operations.

4. The imaging device according to claim 1, further comprising;
a device isolation region that is formed between adjacent pixel portions to each other in the semiconductor substrate
wherein at least a part of the floating gate is formed on an upper side of the device isolating region.

5. The imaging device according to claim 1, further comprising:
a wiring portion that electrically connects the photoelectric converting film to the floating gate and that transmits a quantity of the charges or a change in an electric potential from the photoelectric converting film to the floating gate.

6. The imaging device according to claim 5, further comprising:
a device isolation region is formed between the adjacent pixel portions to each other in the semiconductor substrate,
wherein the wiring portion is formed on the device isolation region or the floating gate extended over a gate oxide film which is formed between the semiconductor substrate and the floating gate and which is thicker than the other portions of the imaging device.

7. The imaging device according to claim 1, further comprising:
a color filter that is formed on the photoelectric converting film.

8. The imaging device according to claim 1, further comprising:
a plurality of photoelectric converting layers that have different spectral characteristics from each other are ed stacked on the semiconductor substrate.

9. The imaging device according to claim 1, further comprising;
a writing transistor includes:
at least one of photodiodes below the photoelectric converting film in each of the pixel portions,
a control gate setting the photodiode as a source and capable of directly controlling an electric potential of a channel region, and
a floating gate electrically isolated from the channel region, and
wherein the writing transistor enables an injection of the charges into the floating gate by controlling an electric potential of the control gate.

10. The imaging device according to claim 9, wherein a plurality of photodiodes are provided in different depths from each other with respect to a surface of the semiconductor substrate.

11. A method of driving an imaging device including;
a semiconductor substrate;
a photoelectric converting film above the semiconductor substrate, generating charges according to incident light; and
a plurality of pixel portions that receive the charges from the photoelectric converting film,
wherein each of the pixel portions includes:
a floating gate that is electrically connected to the photoelectric converting film; and
a transistor that has a threshold voltage to fluctuate according to an electric potential of the floating gate; the method comprising;
transmitting a quantity of the charges or change in an electric potential from the photoelectric converting film to the floating gate and detecting a value of the threshold voltage fluctuating corresponding to the electric potential of the floating gate, thereby outputting a signal.

12. The method of driving an imaging device according to claim 11, further comprising:
reading the threshold voltage by a control gate.

13. The method of driving an imaging device according to claim 12, further comprising:
operating a ramp-up for gradually increasing a voltage of the control gate or a ramp-down for gradually decreasing the voltage of the control gate; and
outputting the threshold voltage as of a moment of a change in an electric potential of a drain of the transistor in the operation of the rump-up or rump-down.

14. The method of driving an imaging device according to claim 11, wherein a device isolation region is formed between adjacent pixel portions to each other in the semiconductor substrate and at least a part of the floating gate is formed on the device isolating region.

15. The method of driving an imaging device according to claim 11, further comprising:
electrically connecting the photoelectric converting film to the floating gate; and
wiring the quantity of the charges or the change in the electric potential from the photoelectric converting film to the floating gate.

16. The method of driving an imaging device according to claim 15, wherein a device isolation region is formed between the adjacent pixel portions to each other in the semiconductor substrate and the wiring is formed on the device isolation region or the floating gate extended over an insulating film which is formed between the semiconductor substrate and the floating gate and is thicker than the other portions of the imaging device.

17. The method of driving an imaging device according to claim 11, wherein a color filter is formed on the photoelectric converting film.

18. The method of driving an imaging device according to claim 11, wherein a plurality of photoelectric converting films having different spectral characteristics from each other are stacks on the semiconductor substrate.

19. The method of driving an imaging device according to claim 11, which includes a writing transistor including: a photodiode below the photoelectric converting film, a control gate controlling the photodiode as a source and capable of directly controlling an electric potential of a channel region, and a floating gate which is electrically isolated from the channel region, the method further comprising:
writing an output signal of the writing transistor by controlling an electric potential of the control gate and by injecting charges into the floating gate.

20. The method of driving an imaging device according to claim 19, wherein a plurality of photodiodes are provided in different depths from each other with respect to a surface of the semiconductor substrate.

21. An imaging apparatus comprising an imaging device according to claim 1.
